(19) United States
(12) Patent Application Publication
(10) Pub. No.: US 2021/0020586 A1
(43) Pub. Date: Jan. 21, 2021

(54) PHOTOVOLTAIC PROTECTION

(71) Applicant: Utica Leaseco, LLC, Rochester, MI (US)

(72) Inventor: Todd KRAJEWSKI, Mountain View, CA (US)

(21) Appl. No.: 17/063,357

(22) Filed: Oct. 5, 2020

Related U.S. Application Data
(63) Continuation-in-part of application No. 16/005,289, filed on Jun. 11, 2018.

(51) Int. Cl. H01L 23/00; H01L 31/048; H01L 31/18

(52) U.S. Cl. CPC H01L 23/562; H01L 31/18; H01L 31/048

(57) ABSTRACT

Various processes can apply pressure and/or heat to a photovoltaic (PV) layer, including processes that integrate solar cells into different types of industrial glass such as an autoclave lamination process. The disclosure describes techniques that can be used on the PV layer to eliminate point loads caused by such processes and protect the PV layer from damage. In an aspect, a method for producing an intermediate PV component protected from mechanical damage in one or more subsequent processing steps is described, where the method includes disposing a protective material on a PV layer having topographical height changes, processing the protective material to provide a planar surface made of the protective material on one or both sides of the PV layer, and providing the PV layer with planarized topographical height changes as the intermediate PV component to the one or more subsequent processing steps for further processing.

### CROSS-REFERENCE TO RELATED APPLICATION

The present application is a Continuation-in-Part of U.S. Non-Provisional patent application Ser. No. 16/005,289, titled “Planarization of Photovoltaics” and filed on Jun. 11, 2018, the contents of which are incorporated herein by reference in their entirety.

### TECHNICAL FIELD

This disclosure relates to the planarization of photovoltaic layers, and in particular, to the use of various materials, structures, devices, and processes that enable the incorporation of photovoltaics into components produced by different lamination processes.

### BACKGROUND

Photovoltaics or PVs are optoelectronic devices that are made of semiconductor materials that exhibit the photovoltaic effect, that is, materials that produce a voltage and/or electric current when exposed to light. In some applications, photovoltaics (also referred to cells of a PV (PV cells) or also as solar cells) are disposed, placed, or fabricated in at least one of the layers in a stack of layers that form an optoelectronic system or component. A layer with photovoltaics may be referred to as a PV layer. The topography or surface of the PV layer is typically not flat or planar as it can contain various types of surface irregularities, including but not limited to front (or back) metallization, tabs, connectors, busbars, joints, or other like structures that protrude from the surface of the PV layer or form depressions on the surface of the PV layer, causing the PV layer surface to be uneven in certain spots.

For certain industrial applications, an optoelectronic system or component, and therefore the PV layer that is part of that component, can be embedded, integrated, or incorporated between layers of a rigid material (e.g., glass) for lamination. One of the processes (but not the only one) that is used for making industrial components with integrated PV layers is the autoclave lamination process. This process includes an initial “de-airing” step that can place a structure having a PV layer into compression with pressure (e.g., 1 bar) before any heating is applied. The autoclave lamination process itself can provide pressurization (e.g., greater than 10 bar) simultaneously with heating. In both instances (e.g. during “de-airing” or autoclave lamination), the PV layer can be subjected to localized point loads because of the uneven topography or surface of the PV layer. This can lead to certain defects such as cracking and/or shunting in the PV layer, which can reduce the performance and/or reliability of the optoelectronic component, and can also negatively impact the production yield rate.

### BRIEF DESCRIPTION OF THE DRAWINGS

FIG. 1A illustrates an example of a PV layer.

FIGS. 1B-1E illustrate examples of different structures with a PV layer cracking due to the topography of the PV layer.

FIGS. 2A-2D illustrate examples of topographical height changes on one or both sides of a PV layer due to protrusions from the PV layer.

FIG. 2E illustrates an example of a topographical height changes due to overlapping PV layers.

FIGS. 3A-3H illustrate examples of different structures with a planarized PV layer that are produced as an intermediate PV component protected from mechanical damage once provided to one or more subsequent processing steps.

FIGS. 4A-5J illustrate examples of various steps for constructing a structure with a planarized PV layer that is to be provided as an intermediate component.

FIG. 5 illustrates an example of a top view of a structure with a planarized PV layer with lamination.

FIGS. 6A-6D illustrate examples of localized planarization for different topographies of PV layers.

FIGS. 7A-7D illustrate other examples of localized planarization for different topographies of PV layers.

FIG. 8 illustrates an example of a method for producing an intermediate PV component protected from mechanical damage.

FIG. 9 illustrates another example of a method for producing an intermediate PV component protected from mechanical damage.

### SUMMARY OF THE DISCLOSURE

The following presents a simplified summary of one or more aspects in order to provide a basic understanding of such aspects. This summary is not an extensive overview of all contemplated aspects, and is intended to neither identify key or critical elements of all aspects nor delineate the scope of any or all aspects. Its purpose is to present some concepts of one or more aspects in a simplified form as a prelude to the more detailed description that is presented later.

In an aspect, a method for producing an intermediate photovoltaic (PV) component protected from mechanical damage in one or more subsequent processing steps is described, the method including disposing a protective material on a PV layer having topographical height changes, the topographical height changes extending from surfaces on one or both sides of the PV layer prior to the protective material being disposed on the PV layer, a thickness of the protective material being based on a thickness of the topographical height changes. The method further including processing the protective material to provide a planar surface made of the protective material on one or both sides of the PV layer, the planar surface sufficiently planarizing the topographical height changes to protect the PV layer from mechanical damage caused by application of pressure on the topographical height changes during the one or more subsequent processing steps. The method further including providing the PV layer with the planarized topographical height changes as the intermediate PV component to the one or more subsequent processing steps for further processing.

In another aspect, a light-capturing component protected from mechanical damage and to be provided to one or more subsequent processing steps is described that includes a photovoltaic (PV) layer; and a protective material disposed on the PV layer. The PV layer has topographical height changes, the topographical height changes extending from surfaces on one or both sides of the PV layer prior to the protective material being disposed on the PV layer, a thickness of the protective material being based on a thickness of the topographical height changes. The protective material is processed to provide a planar surface made of the protective material on one or both sides of the PV layer, the planar surface sufficiently planarizing the topographical height changes to protect the PV layer from mechanical damage caused by application of pressure on the topographical height changes during the subsequent processing step.

in yet another aspect, a method for producing an intermediate photovoltaic (PV) component protected from mechanical damage in one or more subsequent processing steps is described, the method including disposing a protective material on one or both sides of a PV layer having topographical height changes, the topographical height changes extending from surfaces on one or both sides of the PV layer prior to the protective material being disposed on the PV layer, and a thickness of the protective material being based on a thickness of the topographical height changes. The method further including disposing a first release layer over the PV layer with the protective material and a second release layer under the PV layer with the protective material. The method further including modifying a physical form of the protective material to provide a planar surface made of the protective material on one or both sides of the PV layer, the planar surface sufficiently planarizing the topographical height changes to protect the PV layer from mechanical damage caused by application of pressure on the topographical height changes during a subsequent processing step. The method further including removing the first and second release layers and providing the PV layer with the planarized topographical height changes as the intermediate PV component to the one or more subsequent processing steps for further processing.

### DETAILED DESCRIPTION

This disclosure describes various materials, structures, devices, and processes that enable an intermediate photovoltaic (PV) component protected from mechanical damage in one or more subsequent processing steps, such as different lamination processes, for example. In particular, this disclosure describes techniques for planarization of PV layers to eliminate the localized point loads caused by the uneven topography of the PV layer (e.g., topographical height changes from protrusions or overlapping PV layers). As used herein the terms “photovoltaics,” “PVs,” “PV cells,” and “solar cells” may be used interchangeably to refer to one or more portions of an optoelectronic system or component that produce voltage and/or electric current when exposed to light. It is also to be understood that a reference to a single “photovoltaic,” “PV,” “PV cell,” and “solar cell” may also refer to instances of multiples of such devices or structures, including instances in which the multiples of such devices or structures are interconnected in a string or array. A PV layer may refer to a layer (e.g., epitaxial layer, semiconductor layer) that includes one or more photovoltaics, PVs, PV cells, and/or solar cells.

In one example, multiple PV cells can be fabricated, formed, or otherwise assembled on a substrate to produce a PV layer. The different cells (e.g., PV cells or solar cells) of the PV layer can be coupled together via shingling (e.g., to form strings) or an interconnect disposed upon the surface (e.g., front-side or back-side) of the PV layer. The shingling or placement of the interconnect (as well as contacts) results in one or more protrusions from the surface of the PV layer (e.g., the PV layer does not have a planar surface). Eventually, the PV layer is assembled among a stack of other layers, which may include glass (or other laminates) as well as intermediate layers between the PV layer and the glass. Because the resulting structure of the PV layer has one or more surfaces that are non-planar (e.g., locally non-planar or uneven) from surface irregularities or topographical height changes (e.g., protrusions and/or depressions, PV layer overlap) that can cause point loads during a fabrication processing (e.g., autoclave lamination), applied forces (e.g., pressure) that are incidental to the fabrication process can be localized around the irregularities or height changes. If the applied force is too strong, then the PV layer can crack or be otherwise damaged, rendering one or more PV cells in the PV layer useless. Therefore the performance and/or reliability of the optoelectronic component is reduced as a result of the point loads caused by the surface irregularities or height changes. This can have a negative impact on the yield rate of the production of optoelectronic component as well.

To eliminate or reduce the incidence of cracking on the PV layer, the PV layer can be at least partially embedded or covered by a material (e.g., a planarization material) to create one or more planar surfaces on the PV layer. This provides protection for an intermediate PV component before it is introduced to other processes that can crack or damage the component. For example, the PV layer and an interconnect that protrudes from a surface of the PV layer can be embedded within a layer of another material such as a thermoplastic. Thus, when a stack of layers that form an optoelectronic component and include the at least partially embedded PV layer is then subjected to the vacuum or when the optoelectronic component is laminated/autoclaved, for example, the force that is applied on the PV layer as part of these fabrication processes is distributed across the planarized surface of the PV layer and its interconnect rather than localized around a smaller region where the interconnect is located. As a result, cracking (and/or shunting) of the PV layer that would otherwise result near the location of the interconnect can be eliminated or at least reduced. A similar approach may be used when PV layers overlap and the overlap region produces a topographical height change that can cause local cracking.

The planarization of surface irregularities or height changes of the PV layer (e.g., protrusion(s) and/or depression(s), PV layer overlaps) can be performed by placing the PV layer with its surface irregularities or height changes between two layers of planarization material to form a stack of layers. In some instances, planarization of the PV layer may be performed using a single layer of planarization material. The planarization materials can include thermoplastics or thermoset films. The stack of layers can then be disposed within a vacuum structure (e.g., a vacuum bag, chamber, or gasket) with a heat source. Air or gas that is in the layers can be pumped out to create a vacuum, and the heat source can heat the planarization material, causing the planarization material to begin to soften and changes its form. Force can then be applied to allow for the planarization material to mold or deform around the PV layer such that the PV layer and its surface irregularities or height changes are at least partially covered, suspended, or disposed within the resulting planarization material. That is, the planarization material's physical form is changed (e.g., through heat and/or pressure) to encapsulate at least part of the PV layer and its surface irregularities or height changes in order to produce one or more planar surfaces made of the planarization material. This planarized PV layer, which now has one or more planar surfaces as a result of being at least partially embedded in the planarization material, can then be used to assemble an optoelectronic system. That is, the planarized PV layer can be an intermediate PV component provided to one or more subsequent processes that are needed to eventually make the optoelectronic system.

This disclosure describes a solution to the problem of cracking and/or shunting caused by localized point loads on a PV layer by providing protection when processed during different fabrication processes, including autoclaving lamination processes. This solution, through the planarization of the PV layer to eliminate or reduce point loads, allows for the integration of optoelectronic components (e.g., solar cells) into industrial gas application, for example, while using standard production or fabrication processes. This is particularly important for applications where the rigid lamination material (e.g., glass) may be curved, as autoclaving lamination is the most practical, and in some cases, only production process that is viable for those types of shapes. Moreover, the structures and techniques disclosed herein in connection with making planarized PV layers can increase the yield rate of the production of PVs for various applications, including industrial glass lamination applications.

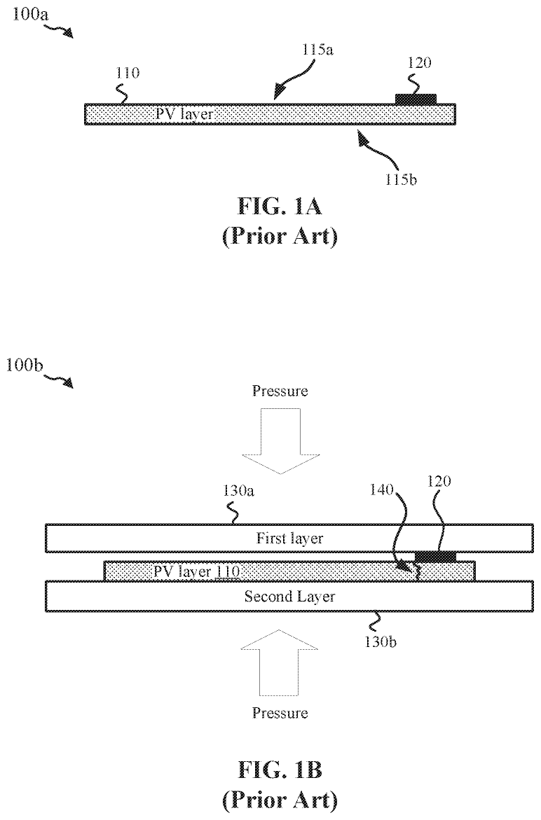

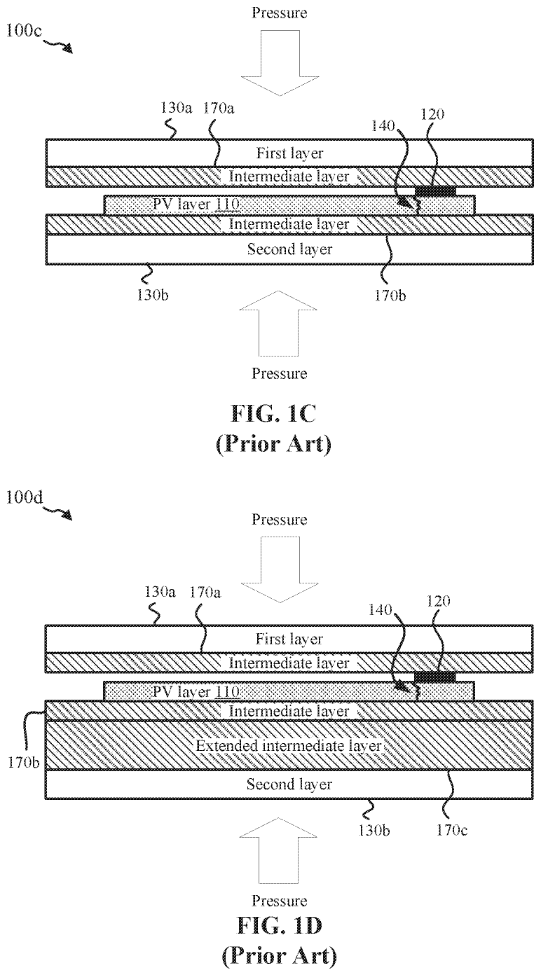

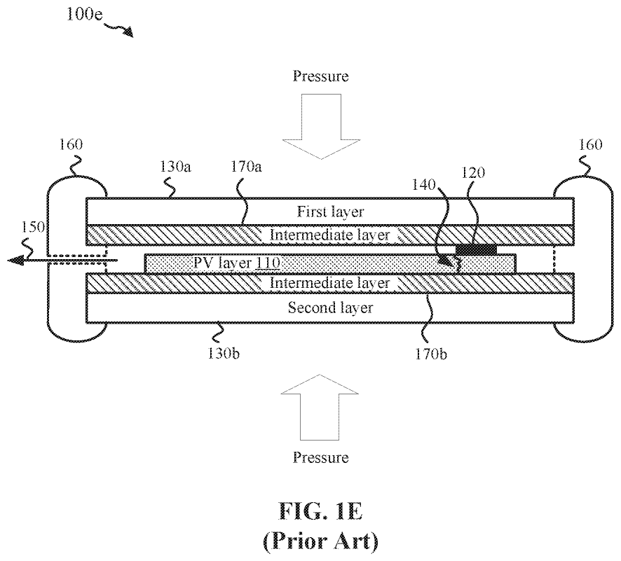

FIG. 1A illustrates a diagram 100a showing a structure that includes a PV layer 110 having a protrusion 120 on a first surface 115a. As shown, the PV layer 110 does not have a protrusion or any other surface irregularity (e.g., electrical and/or mechanical components of PV cells) or topographical height change on a second surface 115b. The protrusion 120 can be representative any number of surface irregularities or height changes in a PV layer 110, for example, the protrusion 120 can represent a busbar providing an interconnect between different PV cells in the PV layer 110, allowing for the flow of current from the different PV cells. Other surface irregularities that can create a protrusion include contacts (e.g., metal contacts upon the surface of the PV layer 110), tabs (e.g., thinner or narrower forms of busbars that reduce shading of the PV cells), and the like. Though the protrusion 120 is shown on a top side of the PV layer 110 (on the first surface 115a), the protrusion 120 can also be on a bottom side of the PV layer 110 (on the second surface 115b), or there could be instances in which there are protrusions 120 on both sides of the PV layer (on the first surface 115a and on the second surface 115b). Moreover, while a single protrusion 120 is shown, this is merely for illustration purposes, a single protrusion 120 can be representative of multiple protrusions whether they are topographically next to each other or not. It is to be understood that the terms “top side” and “bottom side” as used in this context are intended to indicate the position of the protrusion 120 in connection with the orientation of the structure shown in the diagram 100a of FIG. 1A and are not intended to provide an indication of whether a side is a light-facing side or not.

The PV layer 110 can include cells (e.g., PV cells) made of semiconductor materials including one or more of gallium arsenide (GaAs), copper indium gallium selenide (also known as CIGS), cadmium telluride (CdTe), perovskites, silicon (Si), or other materials that exhibit the photovoltaic effect in which voltage and/or electric current are generated in a semiconductor material upon exposure to light. This can also include thin film photovoltaic (or solar) cells that are made by depositing thin layers of material on a substrate (e.g., a Si, GaAs, aluminum foil, steel, etc. substrates).

In an example, the PV layer 110 can include a thin film PV material on which the PV cells are made or embedded, where the thin film PV material can be one or more of CdTe, CIGS, amorphous thin-film silicon (a-Si), GaAs, or perovskites. The PV layer 110 may include crystalline silicon (c-Si) made of multicrystalline silicon or monocrystalline silicon. Moreover, the PV layer 100 may include PV cells made of a heterojunction with intrinsic thin layer (HIT) structure having a thin crystalline silicon layer surrounded by one or more ultra-thin amorphous silicon layers. In some instances, the PV layer 110 may be made of flexible PV cells to allow the PV layer 110 to conform to different shapes. For example, the PV layer 110 can be a flexible thin film made by an epitaxial lift-off (ELO) process or other similar process.

As described above, a PV layer can be one of the layers in a stack of layers that form an optoelectronic system or component. The PV layer can be part of an intermediate PV component that is to be further processed. The optoelectronic component along with the PV layer can be embedded, integrated, or incorporated between layers of a rigid material (e.g., glass) for lamination and to produce an industrial component or product that can be used in a wide range of applications.

One of the processes that is used for making industrial components with integrated PV layers is the autoclave lamination process. The autoclave lamination process (and similar processes) can include an initial or first step, generally referred to as a “de-gassing” step in which vacuum is applied to remove gas from the sample (e.g., assembled stack of layers) being processed—layers of the stack are subjected to up to 1 bar of pressure as a result. The “de-gassing” step can also include some form of heating, where, for example, the sample goes into an oven (e.g., a conveyor furnace) and is heated up to 75-80 degrees Celsius (° C.). The “de-gassing” step therefore reduces moisture and gases within the layers of the stack and adheres the layers together. In some instances, the “de-gassing” step can be a standalone step that need not be performed in connection with an autoclave lamination process or any other similar lamination process. FIGS. 1B-1E illustrate examples of different structures in which a PV layer cracks (or shunts) due to forces being applied to an uneven or non-planar topography of the PV layer. These forces may be the result of “de-gassing” or similar vacuum step being performed or due to other processes in which the application of pressure or force on a PV layer results from the process.

FIG. 1B shows a diagram 100b in which a stack of layers (e.g., at least part of an optoelectronic component) is subjected to additional processing after being assembled. In the example of FIG. 1B, the stack of layers includes the PV layer 110 with the protrusion 120, as well as a first layer 130a disposed or placed over the PV layer 110 and a second layer 130b disposed or placed below the PV layer 110. In other words, the PV layer 110 is placed between or is “sandwiched” by the first layer 130a and the second layer 130b. The first layer 130a and the second layer 130b need not be of the same thickness; however, the first layer 130a and the second layer 130b may generally be of the same size and may have their edges substantially aligned.

The first layer 130a and the second layer 130b can be planar layers that provide rigidity and/or to protect the other layers in the stack from damage to due mechanical abrasion and/or environmental exposure. In a typical industrial or commercial application, the first layer 130a and the second layer 130b are planar layers made of glass or other similarly rigid, transparent material. In other applications, the first layer 130a and the second layer 130b can instead be non-planar or non-uniform layers. For example, the first layer 130a and the second layer 130b may be curved.

Materials other than glass can also be used for the first layer 130a and the second layer 130b. For example, polycarbonate can be used instead of glass for the first layer 130a, while steel, aluminum, carbon fiber composites, fiber glass, engineered thermoplastics, and reinforced thermoplastics can be used instead of glass for the second layer 130b. In an aspect, the first layer 130a may be a top laminate layer associated with the front or light receiving side of the PV layer 110, while the second layer 130b may be bottom laminate layer associated with a back or dark side of the PV layer 110.

As described above, the first layer 130a and the second layer 130b can be made of rigid materials. The rigidity associated with the first layer 130a and the second layer 130b can be greater than the rigidity associated with the PV layer 110. A greater rigidity in this case can refer to a greater stiffness based on, for example, Young's modulus. In some examples, the rigidity associated with the first layer 130a can be different than the rigidity associated with the second layer 130b.

In an example, the stack can be placed inside a vacuum structure to perform a “de-gassing” or similar step. The vacuum structure can be a vacuum bag (e.g., Teflon bag, polytetrafluoroethylene (PTFE) bag) or some form of vacuum container that is used to pull vacuum and remove gas or air from the stack of layers. FIG. 1E, which is described in more detail below, shows an example in which a vacuum structure 160 is a gasket placed around the stack of layers that includes the PV layer 110. When vacuum is pulled and air/gas 150 is removed from the stack of layers inside the vacuum structure, forces (e.g., pressure) are applied to the first layer 130a and the second layer 130b of the stack (see e.g., arrows showing pressure being applied). Other techniques may also be used to apply forces or pressure to the first layer 130a and/or the second layer 130b.

The application of forces on the first layer 130a and the second layer 130b in turn applies a force on the protrusion 120, which localizes a large amount of the applied force onto a small surface area of the PV layer 110 near the protrusion 120. When the localized force applied is too strong, then one or more cracks 140 or some other defects (or shunts) can occur in the PV layer 110. The damage caused to the PV layer 110 by the crack 140 can render at least part of the PV layer 110 useless, which may reduce not only the efficiency of the overall optoelectronic component, but if the sample is sufficiently damaged and needs to be scrapped, the yield rate of the fabrication process is also reduced.

FIG. 1C shows a diagram 100c in which an intermediate layer 170a is disposed or placed between the PV layer 110 and the first layer 130a, and an intermediate layer 170b is disposed or placed between the PV layer 110 and the second layer 130b. The intermediate layer 170a and the intermediate layer 170b can be referred to as interlayers and can be at least partially made of a thermoplastic such as polyvinyl butyral (PVB). These intermediate layers can provide structural rigidity to the stack of layers, as well as provide additional properties such as adhesion (e.g., to keep the different layers joined together), infrared (IR) blocking (e.g., to reduce heat that propagated through the stack), or ultraviolet (UV) blocking (e.g., to reduce UV rays from propagating through the stack).

Similarly to the structure in FIG. 1B, pressure can be used that results in forces being applied to the first layer 130a and the intermediate layer 170a of the stack as well as the second layer 130b and the intermediate layer 170b of the stack. This in turn applies a force on the protrusion 120, which can produce one or more cracks 140 or some other defects (or shunts) on the PV layer 110. In an example, by having vacuum pulled and air/gas is removed when the stack of layers is placed inside a vacuum structure as part of a “de-gassing” step, forces may end up being applied to the first layer 130a and the intermediate layer 170a of the stack as well as the second layer 130b and the intermediate layer 170b of the stack.

FIG. 1D shows a diagram 100d in which the stack of layers is similar to the one in FIG. 1C with an extended intermediate layer 170c being disposed or placed between the intermediate layer 170b and the second layer 130b. The extended intermediate layer 170c can also be at least partially made of a thermoplastic such as PVB. Again, one or more cracks 140 or some other defects (or shunts) can occur in the PV layer 110 as a result of the forces produced from some process, such as when the stack of layers is inside a vacuum structure and vacuum is pulled and air/gas is removed.

FIG. 1E shows a diagram 100e having a similar stack of layers as the one shown in FIG. 1C. In this example, as described above, a gasket is used as the vacuum structure 160 to seal around the stack of layers to pull vacuum and remove air/gas 150 from the stack of layers. Like FIGS. 1B-1D above, one or more cracks 140 or some other defects (or shunts) can occur in the PV layer 110 as a result of the forces produced by the process, which in this case is a vacuum operation.

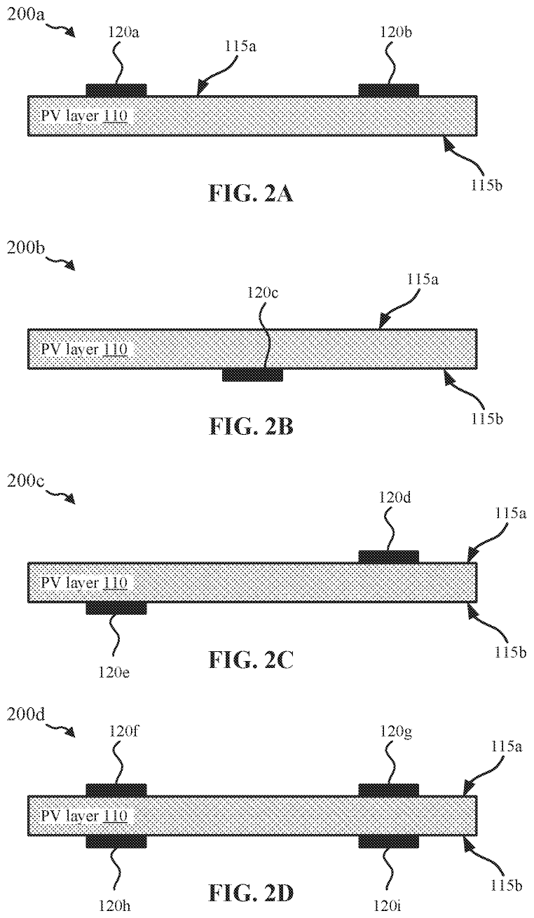

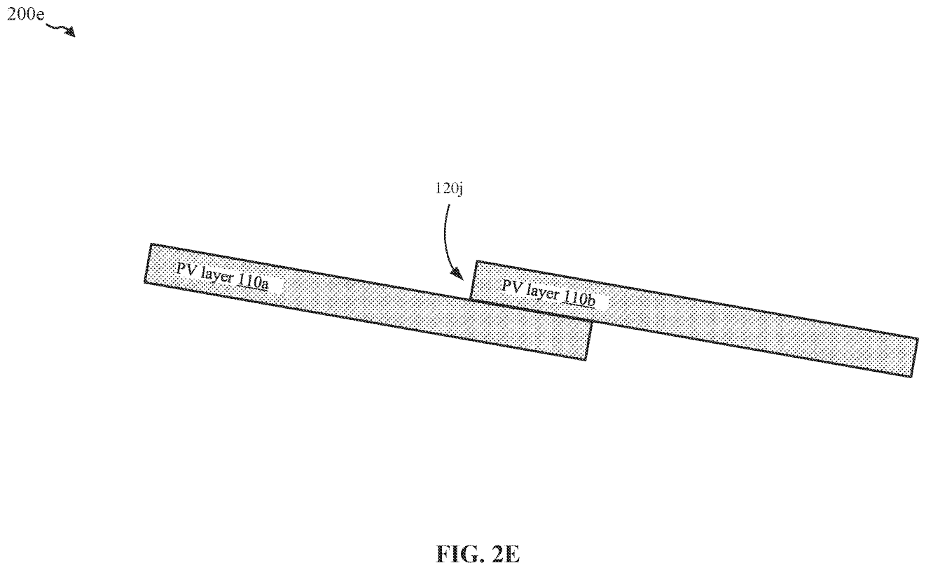

FIGS. 2A-2D provide examples of topographical height changes on one or both sides of a PV layer due to protrusions from the PV layer. Topographical height changes or surface irregularities may include protrusions extending outwards from a surface of a PV layer, depressions extending inwards from the surface of the PV layer, or height changes caused when PV layers overlap. The examples in FIGS. 2A-2D show protrusions by similar aspects may apply to depressions.

In FIG. 2A, a diagram 200a shows an example where the PV layer 110 has multiple protrusions (e.g., protrusions 120a and 120b) on the first surface 115a (e.g., on a top surface) of the PV layer 110.

In FIG. 2B, a diagram 200b shows an example where the PV layer 110 has one protrusion (e.g., protrusion 120c) on the second surface 115b (e.g., on a bottom surface) of the PV layer 110.

In FIG. 2C, a diagram 200c shows an example where the PV layer 110 has multiple protrusions (e.g., protrusions 120d and 120e). In this example, the protrusion 120d is on the first surface 115a (e.g., on a top surface) of the PV layer 110 and the protrusion 120e is on the second surface 115b (e.g., on a bottom surface) of the PV layer 110.

In FIG. 2D, a diagram 200d shows an example where the PV layer 110 has multiple protrusions (e.g., protrusions 120f, 120g, 120h, and 120i). In this example, the protrusions 120f and 120g are on the first surface 115a (e.g., on a top surface) of the PV layer 110 and the protrusions 120h and 120i are on the second surface 115b (e.g., on a bottom surface) of the PV layer 110.

FIG. 2E shows a diagram 200e in which the an example of a topographical height changes due to overlapping PV layers. In this example, a topographical height change 120j occurs when a PV layer 110b overlaps a PV layer 110b when the PV layers are being mechanically and/or electrically connected as part of a larger array of PV layers. The application of a force where the PV layers overlap can affect the mechanical and/or electrical connection between the PV layers.

It is to be understood that more or fewer protrusions or other types of topographical height changes can occur in a PV layer than as shown in FIGS. 2A-2E. Moreover, these examples are provided to illustrate places or positions in which the application of a force can cause a break, crack, defect, shunt, or some other impairment to a PV layer or component having a PV layer without using the protective techniques described in this disclosure. Those protective techniques involve the use of a protective material that surrounds part or all of the PV layer to planarize one or both surfaces of the PV layer and avoid point contacts where damage can occur.

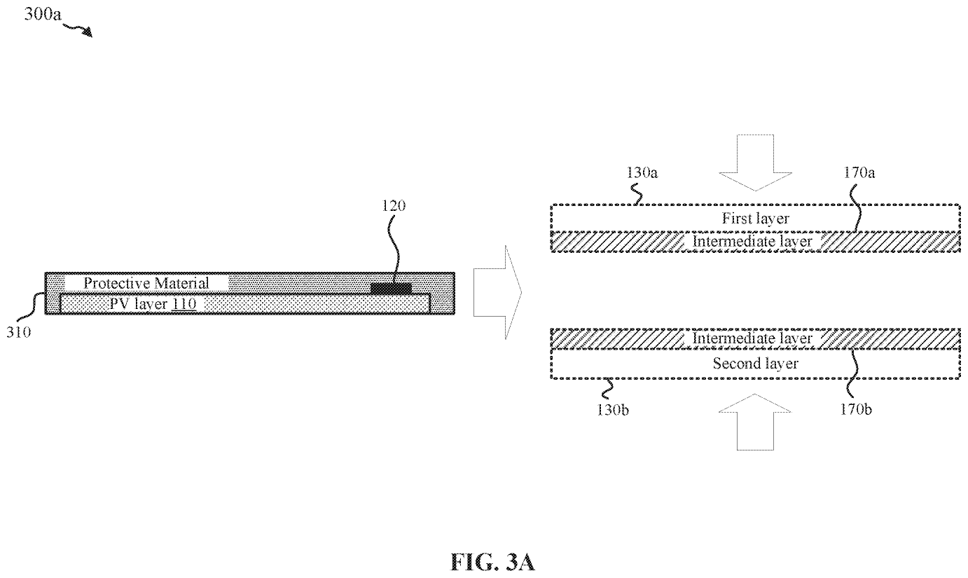

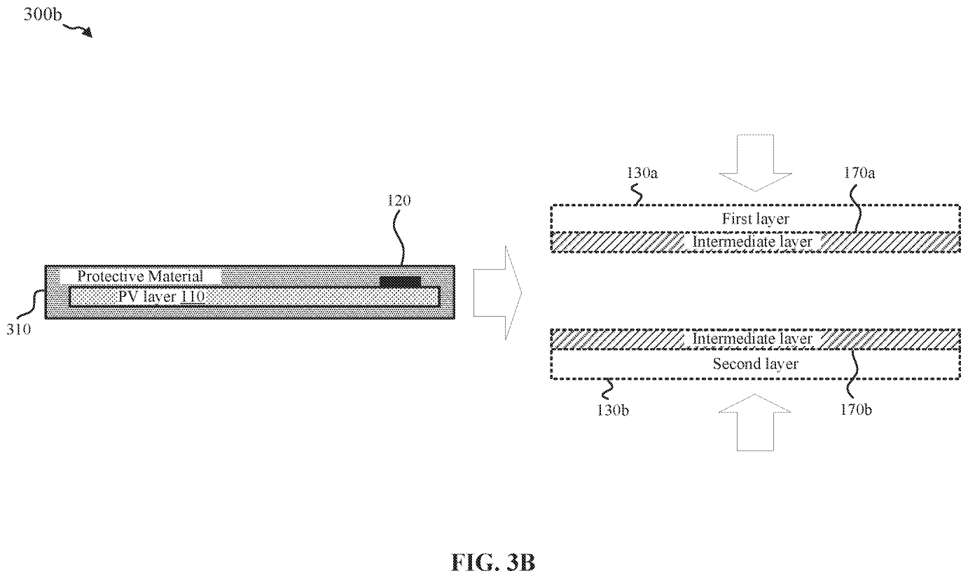

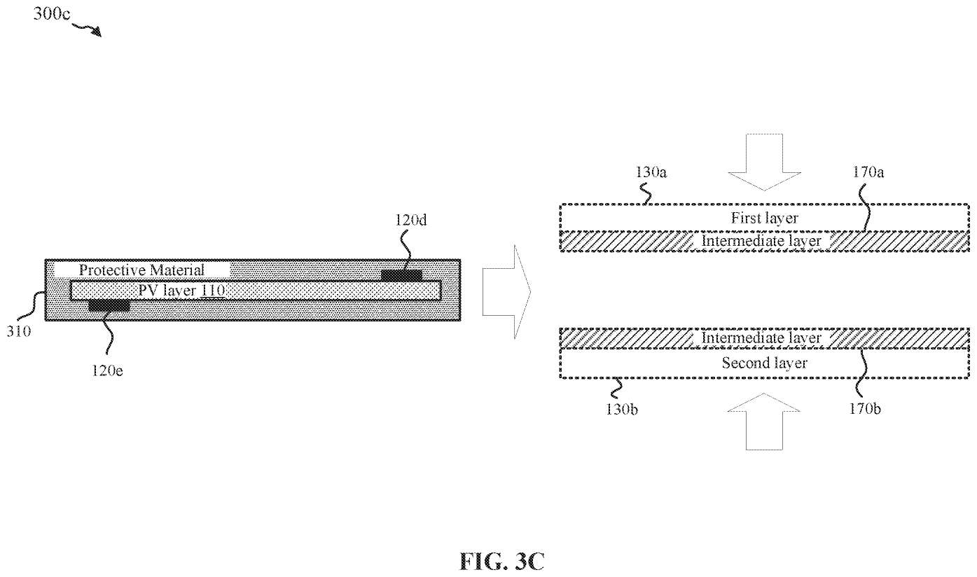

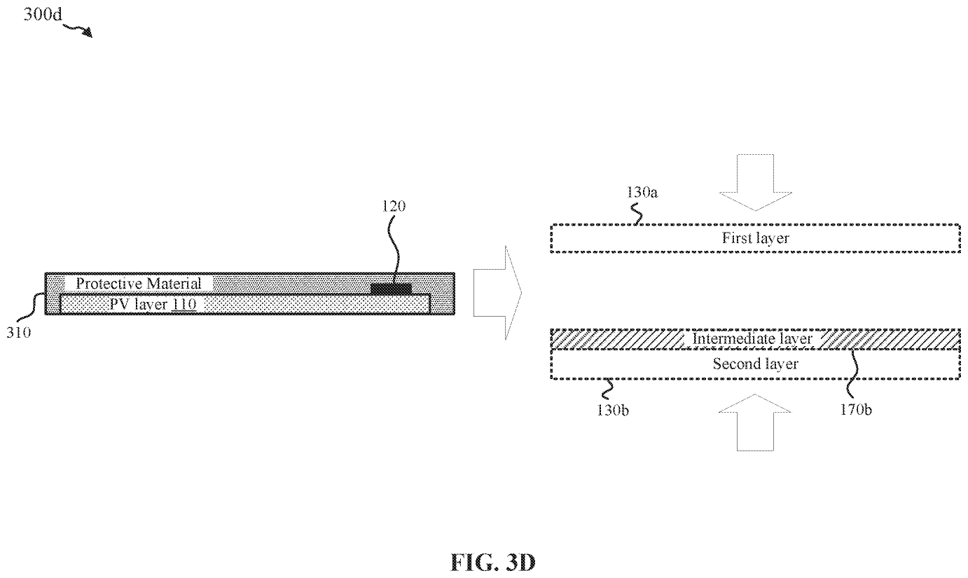

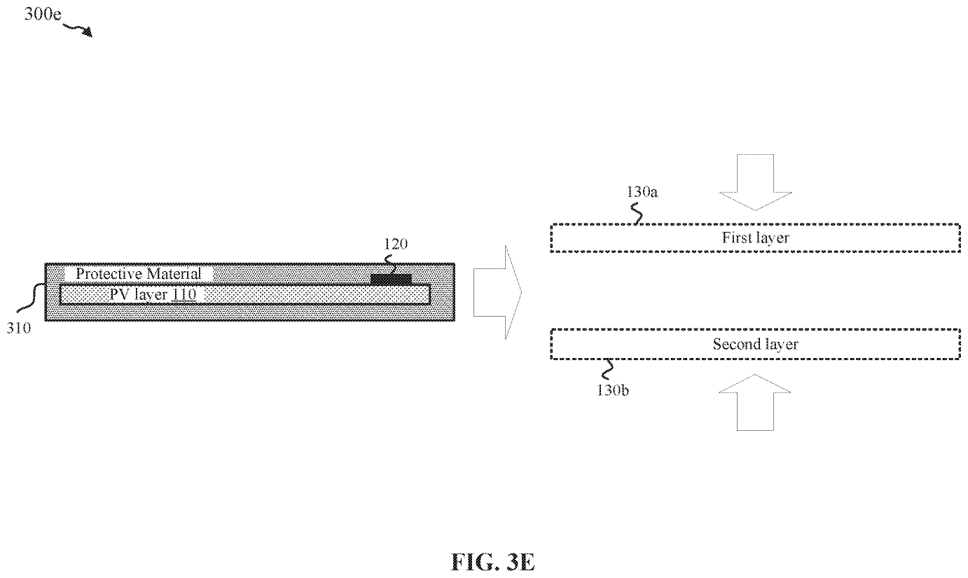

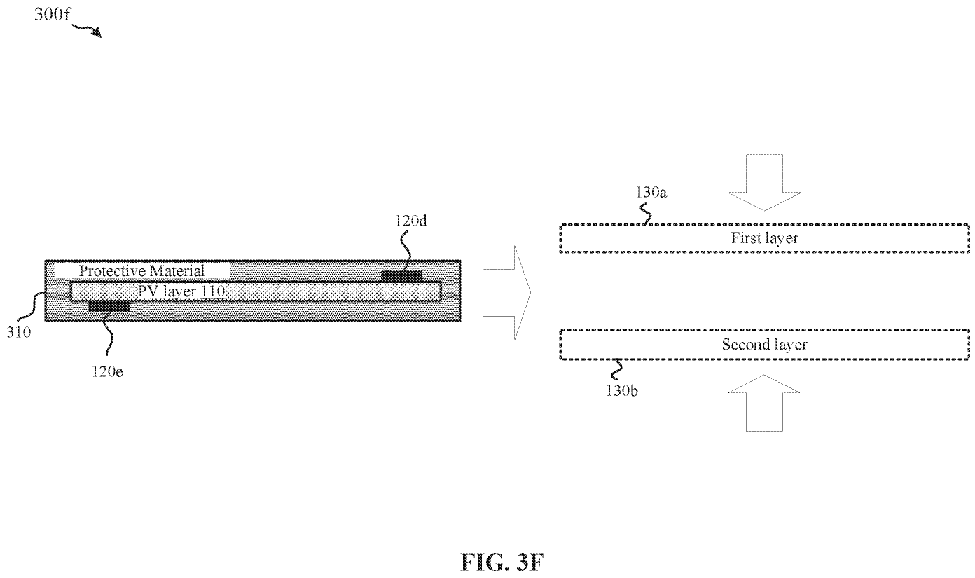

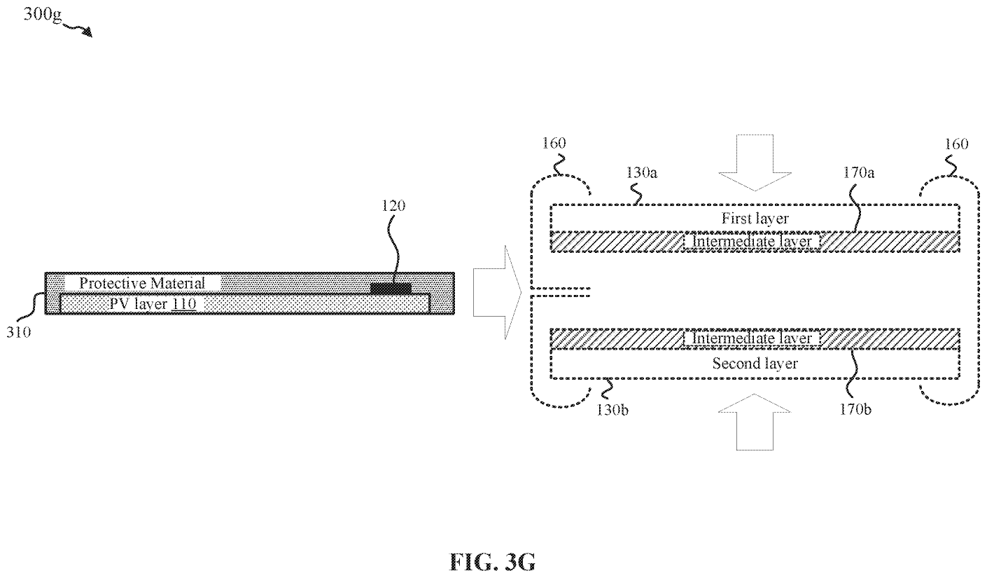

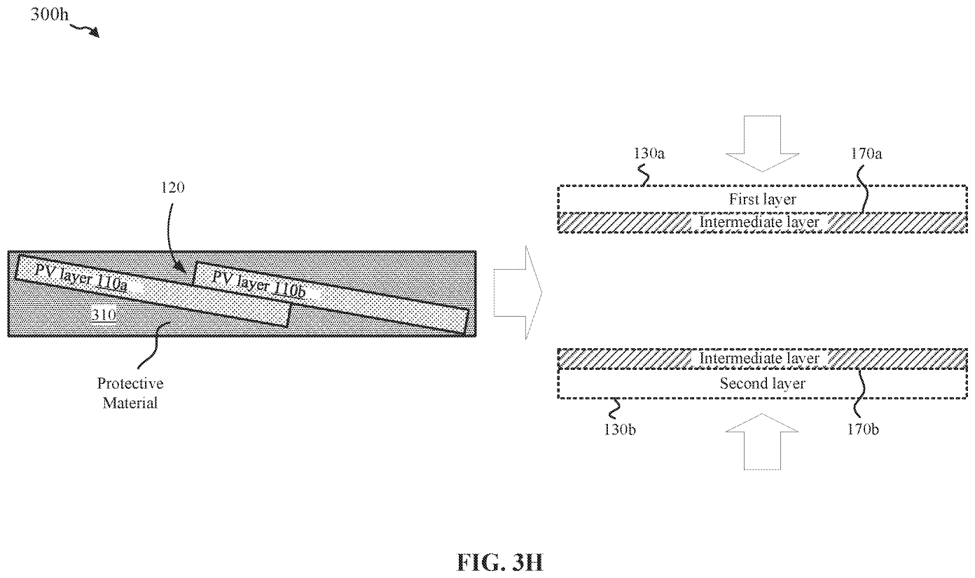

FIG. 3A shows a diagram 300a in which a PV layer 110 is planarized by applying a planarization material 310 that covers at least a top portion or a top surface of the PV layer 110. In an aspect, it is possible to refer to the combination of the PV layer 110, the protrusion 120, and the planarization material 310 as a planarized PV layer. It is to be understood that the terms “top side,” “top surface,” “bottom side,” and “bottom surface” as used in this context are intended to indicate a position in connection with the structure shown in the diagram 300a of FIG. 3A and are not intended to provide an indication of whether a side or surface is a light-facing or not.

The planarized PV layer may be used as an intermediate PV component that is subsequently provided to a process for further processing. In this example, the intermediate PV component (e.g., the planarized PV layer) is provided to form a stack of layers that includes an intermediate layer 170a disposed or positioned between a top, planar side or surface of the planarization material 310 and a first layer 130a. Similarly, the stack of layers further includes an intermediate layer 170b disposed or positioned between a bottom side or surface of the planarization material 310 and/or of the PV layer 110 and the second layer 130b. In one example, the stack of layers can be placed inside a vacuum structure 160 as part of a “de-gassing” step (standalone or otherwise).

As shown in FIG. 3A, the protrusion 120 is covered by the planarization material 310, which similar to the intermediate layers 170a and 170b, can be made of PVB. In some examples, materials other than PVB can also be used for the planarization material 310. The coverage provided by the planarization materials 310 results in the PV layer 110 and the protrusion 120 being at least partially suspended or embedded within planarization material 310. In an aspect, planarized PV layer has a planarized surface (e.g., flat or substantially flat surface) closest to the intermediate layer 170a.

When placed in a vacuum structure and when vacuum is pulled and air/gas is removed from the stack of layers inside the vacuum structure, forces are applied to the first layer 130a and the intermediate layer 170a of the stack, as well as to the second layer 130b and the intermediate layer 170b of the stack. Because these forces are now distributed across the planar surfaces produced by the planarization material 310, a crack, defect, and/or shunt is less likely to occur. That is, the forces are no longer localized near the protrusion 120 and are instead distributed over the entire planar surface provided by the planarization material 310. As a result, the electronic component yield rate of the manufacturing process can increase, which allows for reduced costs and higher-volume production.

FIGS. 3B-3H provide additional examples of intermediate PV components that are provided to form a stack of layers in which a planarization material is used to reduce or eliminate cracks, defects, and/or shunts that may be caused by forces introduced to the stack of layers during a “de-gassing” step or similar step. Details regarding these examples are provided below.

In the diagram 300b of FIG. 3B, the coverage provided by the planarization material 310 results in the PV layer 110 and the protrusion 120 being completely suspended or embedded within planarization material 310. In an aspect, it is possible to refer to the combination of the PV layer 110, the protrusion 120, and the planarization material 310 as a planarized PV layer or intermediate PV component. The intermediate PV component provided to form the stack of layers has one planarized surface (e.g., flat or substantially flat surface) closest to the intermediate layer 170a and another planarized surface closest to the intermediate layer 170b such that the intermediate PV component is between the intermediate layers 170a and 170b.

In the diagram 300c of FIG. 3C, the PV layer 110 has a first protrusion 120a on one surface and a second protrusion 120b on the opposite surface. In this example, the coverage provided by the planarization material 310 results in the PV layer 110 and the protrusions 120a and 120b being completely suspended or embedded within planarization material 310. In an aspect, it is possible to refer to the combination of the PV layer 110, the protrusions 120a and 120b, and the planarization material 310 as a planarized PV layer or intermediate PV component that is provided to form a stack of layers for a subsequent process. The intermediate PV component has one planarized surface (e.g., flat or substantially flat surface) closest to the intermediate layer 170a and another planarized surface closest to the intermediate layer 170b such that the intermediate PV component (e.g., the planarized PV layer) is between the intermediate layers 170a and 170b.

In the diagram 300d of FIG. 3D, the PV layer 110 has the protrusion 120. The coverage provided by the planarization material 310 results in the PV layer 110 and the protrusion 120 being at least partially suspended or embedded within planarization material 310. In an aspect, it is possible to refer to the combination of the PV layer 110, the protrusion 120, and the planarization material 310 as a planarized PV layer or intermediate PV component that is provided to form a stack of layers for a subsequent process. Note that for this example of the stack of layers, the intermediate layer 170a is absent such that the planarization material 310 of the intermediate PV component is in direct contact (e.g., directly bonded) with the first layer 130a when forming the stack of layers. The intermediate PV component has a planarized surface (e.g., flat or substantially flat surface) closest to the first layer 130a.

In the diagram 300e of FIG. 3E, the PV layer 110 has the protrusion 120. The coverage provided by the planarization material 310 results in the PV layer 110 and the protrusion 120 being completely suspended or embedded within planarization material 310. In an aspect, it is possible to refer to the combination of the PV layer 110, the protrusion 120, and the planarization material 310 as a planarized PV layer or intermediate PV component that is provided to form a stack of layers for a subsequent process. Note that for this example of the stack of layers, the intermediate layers 170a and 170b are absent such that the planarization material 310 is in direct contact (e.g., directly bonded) with the first layer 130a and the second layer 130b. The intermediate PV component has one planarized surface (e.g., flat or substantially flat surface) closest to the first layer 130a and another planarized surface closest to the second layer 130b such that the intermediate PV component (e.g., the planarized PV layer) is between the first layer 130a and the second layer 130b.

In the diagram 300f of FIG. 3F, the PV layer 110 has a first protrusion 120a on one surface and a second protrusion 120b on the opposite surface. The coverage provided by the planarization material 310 results in the PV layer 110 and the protrusions 120a and 120b being completely suspended or embedded within planarization material 310. In an aspect, it is possible to refer to the combination of the PV layer 110, the protrusions 120a and 120b, and the planarization material 310 as a planarized PV layer or intermediate PV component. Note that for this example of the stack of layers, the intermediate layers 170a and 170b are absent such that the planarization material 310 is in direct contact (e.g., directly bonded) with the first layer 130a and the second layer 130b. The intermediate PV component has one planarized surface (e.g., flat or substantially flat surface) closest to the first layer 130a and another planarized surface closest to the second layer 130b such that the intermediate PV component (e.g., the planarized PV layer) is between the first layer 130a and the second layer 130b.

In the diagram 300g of FIG. 3G, the planarized PV layer or intermediate PV component is similar to the one described above in connection with FIG. 3A and is provided to form stack of layers similar to the one in FIG. 3A. In this example, however, instead a vacuum structure 160 in the form of a gasket is used to seal around the stack of layers to pull vacuum and remove air/gas from the stack of layers.

In the diagram 300h of FIG. 3H, there are overlapping PV layers 110a and 110b that produce a topographical height change 120. The coverage provided by the planarization material 310 results in the PV layers 110a and 110b, and the topographical height change 120 being completely suspended or embedded within planarization material 310. In an aspect, it is possible to refer to the combination of the PV layers 110a and 110b, the topographical height change 120, and the planarization material 310 as a planarized PV layer or intermediate PV component. The intermediate PV component provided to form the stack of layers has one planarized surface (e.g., flat or substantially flat surface) closest to the intermediate layer 170a and another planarized surface closest to the intermediate layer 170b such that the intermediate PV component is between the intermediate layers 170a and 170b.

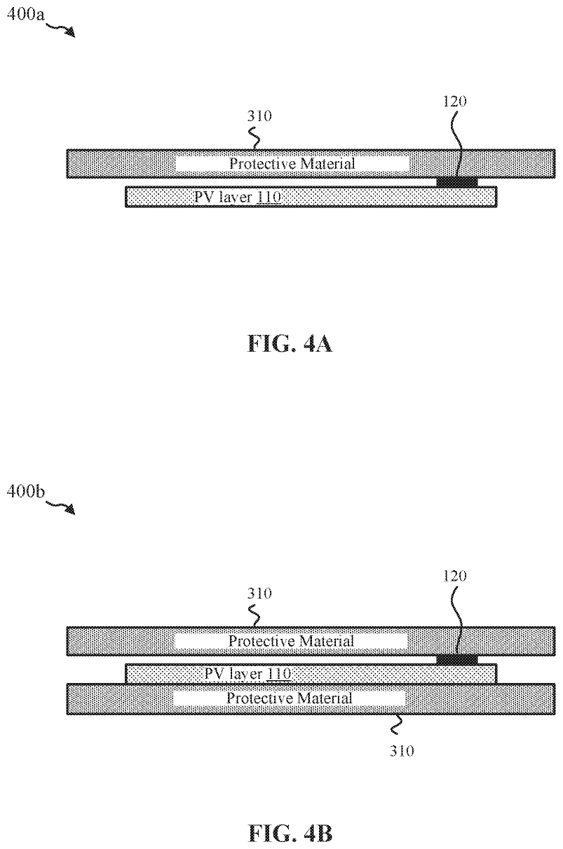

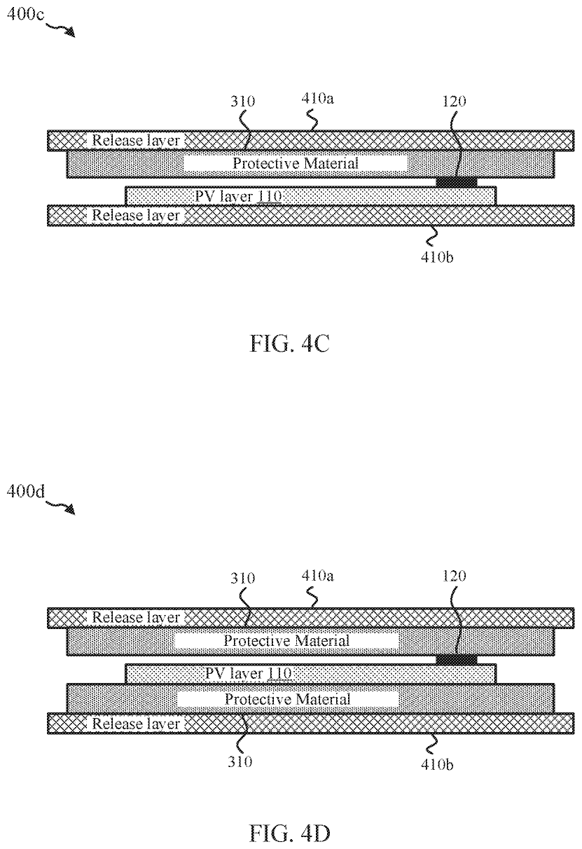

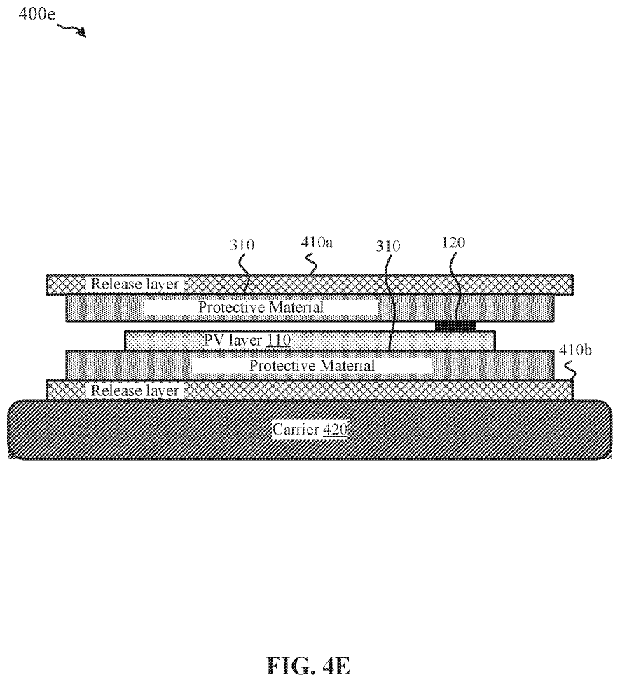

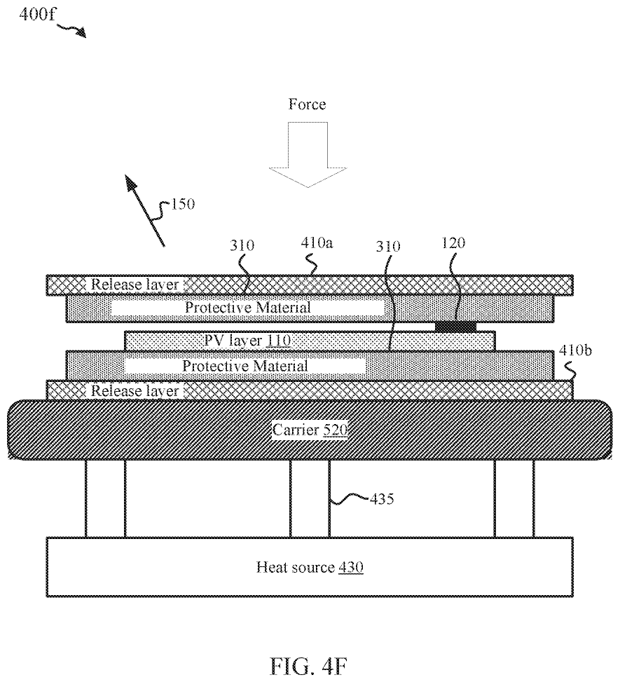

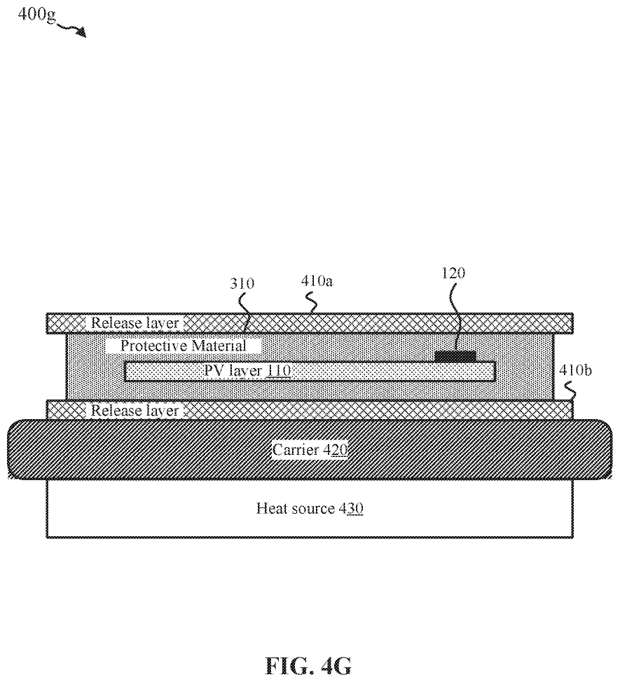

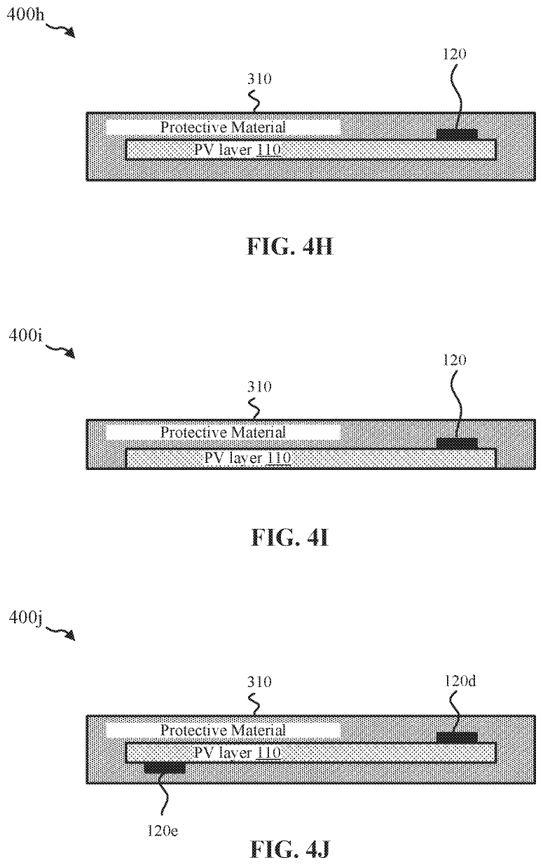

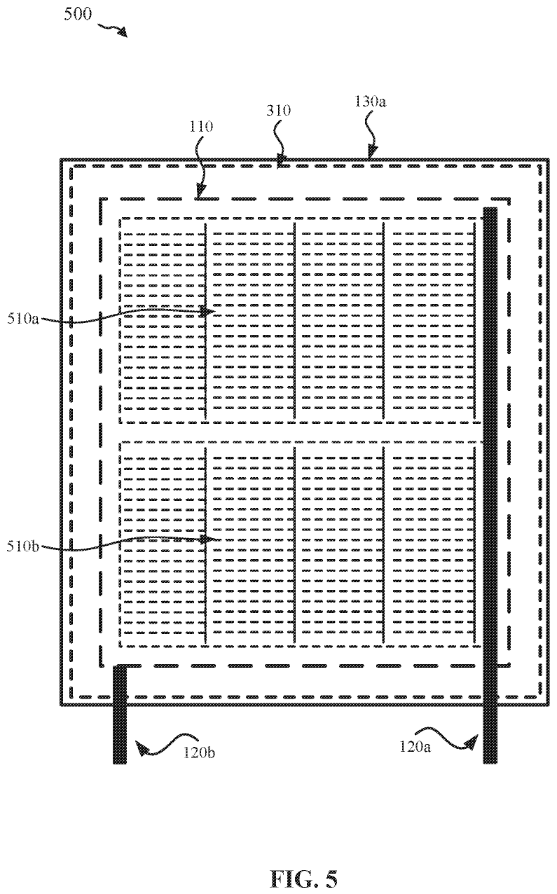

FIGS. 4A-5J illustrate examples of various steps for constructing a structure with a planarized PV layer or intermediate PV component. In FIG. 4A, a diagram 400a shows a stack of layers that is formed by disposing or placing a layer of the planarization material 310 adjacent or next to a top surface of the PV layer 110 with the protrusion 120. The example shown in the diagram 400a of FIG. 4A corresponds to the scenario in which the planarization material 310 is applied to one surface of the PV layer 110. In this example, the stack of layers refers to layers of an intermediate PV structure, which can then be subsequently provided to form another stack of layers for further processing.

In FIG. 4B, a diagram 400b shows a stack of layers that is formed by disposing or placing a layer of the planarization material 310 adjacent or next to a top surface of the PV layer 110 with the protrusion 120 and an additional layer of the planarization material 310 adjacent or next to a bottom surface of the PV layer 110 without the protrusion 120. The example shown in the diagram 400b of FIG. 4B corresponds to the scenario in which the planarization material 310 is applied to both surfaces of the PV layer 110. It is to be understood that the terms “top surface” and “bottom surface” as used in this context are intended to indicate a position in connection with the structure shown in the diagrams 400a and 400b of FIGS. 4A and 4B, respectively, and are not intended to provide an indication of whether a surface is a light-facing surface or not. As mentioned above, the stack of layers in this example refers to layers of an intermediate PV structure, which can then be subsequently provided to form another stack of layers for further processing.

The planarization material 310 that is disposed or placed adjacent to the PV layer 110 can include thermoplastics such as polyvinyl butyral (PVB), Ionomers, thermoplastic polyurethanes (TPU), thermoplastic silicone elastonomers (TPSE), polyolefins (TPO), or thermosets such as ethylene-vinyl acetate (EVA), silicones, or polyolefin elastomers (POE). In one example, each layer of the planarization material 310 can both be approximately 0.1 millimeters (mm) in thickness. In another example, each of the layers of the planarization material 310 in FIG. 4B can have a different thickness.

The same planarization material 310 can be used for each of the layers in FIG. 4B (e.g., both can be PVB). In some implementations, however, the planarization material 310 in each of these layers can be different. For example, the planarization material 310 disposed adjacent the top surface of the PV layer 110 can be a thermoplastic and the planarization material 310 disposed adjacent the bottom surface can be a thermoset. In another example, the planarization material 310 disposed adjacent the top surface of the PV layer 110 can be a thermoplastic such as PVB and the planarization material 310 disposed adjacent the bottom surface can be another thermoplastic such as thermoplastic polyurethane (TPU).

The planarization material 310 can be heated to laminate or cover at least a portion of the PV layer 110 and the protrusion 120. For example, when a single layer of the planarization material 310 is used as in FIG. 4A, the planarization material 310 when heated can change its form to cover or embed a top portion of the PV layer 110 with the protrusion 120 within the planarization material 310. In another example, when two layers of the planarization material 310 are used as in FIG. 54B, the planarization material 310 when heated can change its form to completely cover or embed the PV layer 110 with the protrusion 120 within the planarization material 310.

The PV layer 110 with the protrusion 120 when at least partially embedded within the planarization material 310 provides a planarized PV layer that can have a planar surface at the top made from the planarization material 310 (e.g., when a single layer of the planarization material 310 is used as in FIG. 4A) or can have planar surfaces at the top and bottom made from the planarization material 310 (e.g., when two layers of the planarization material 310 are used as in FIG. 4B).

In FIG. 4C, a diagram 400c shows the same stack of layers described in the diagram 400a of FIG. 4A while additionally including a release layer 410a disposed or placed adjacent or next to the planarization material 310, and further including a release layer 410b disposed or placed adjacent or next to the bottom surface of the PV layer 110 with the protrusion 120.

In FIG. 4D, a diagram 400d shows the same stack of layers described in the diagram 400b of FIG. 4B while additionally including the release layer 410a disposed or placed adjacent or next to the planarization material 310 positioned over the PV layer 110 with the protrusion 120, and further including the release layer 410b disposed or placed adjacent or next to the planarization material 130 positioned below the PV layer 110 with the protrusion 120.

The release layers 410a and 410b can be made from thin sheets of Teflon® or other type of polytetrafluoroethylene (PTFE) or other materials (e.g., silicones) with non-stick properties such that when the planarization material 310 melts or softens by the application of heat, it can be easily ready for assembly with other layers. That is, the release layers 410a and 410b can be easily removed to make a planarized PV layer (e.g., the PV layer 110 with the protrusion 120 having one or two planar surfaces made from the planarization material 310) available as an intermediate PV component for assembly as part of another stack of layers or an optoelectronic component, as discussed herein.

FIG. 4E shows a diagram 400e in which the same stack of layers described above in connection with FIG. 4D is placed on a carrier 420. It is to be understood that the stack of layers shown in the diagram 400e of FIG. 4E is provided by way of illustration and other stacks of layers can be similarly used.

The carrier 420 can be, for example, a high-temperature fiberglass carrier. That is, the carrier 420 can be made of fiberglass (e.g., fiber-reinforced plastic using glass fiber) such that it maintains its structural rigidity under high-temperature conditions. Other materials such as carbon fiber composites, steel, and aluminum can also be used to construct a high temperature carrier. In the example of fiberglass, the softening and melting points of the fiberglass can be significantly higher than the softening and melting points of the planarization material 310. This allows for the various layers of the planarization material 310 to soften or melt when heat is applied while allowing for carrier 420 to remain structurally sound. In some implementations, the stack of layers can instead be placed within a vacuum structure or within a chamber (e.g., autoclave chambers) without the use of a carrier.

FIG. 4F shows a diagram 400f in which the stack of layers on the carrier 420 as shown in FIG. 4E is placed in a condition in which force can be applied. One example, is to place the stack of layer on the carrier 420 inside a vacuum bag (e.g., a Teflon® bag) or chamber and a vacuum is provided. In this scenario, a heat source 430, such as a hot plate with pins (e.g., pins 435 are depicted in the heat source 430) can be used to provide heat. Air/gas 150 can be pumped out such that the chamber has less air within (e.g., a full or partial vacuum). This results in the pressure inside the bag or chamber being less than the atmospheric pressure outside of the bag or chamber.

The heat provided by the heart source 430 is used to soften or melt the layers of the planarization material 310 such that the planarization material 310 changes its form to surround at least partially the PV layer 110 with the protrusion 120. For example, the heat source 430 can be configured to adjusts its temperature such that an increase in temperature results in heat being thermally conducted to the carrier 420, and thereby to the planarization material 310.

When initially placed on the pins of the heat source 430, the carrier 420 with the stack of layers can be positioned away from the heat source 430 as shown in FIG. 4F. In this way, the transfer of heat from the heat source 430 to carrier 420 can be controlled (e.g., slowed down to a desired amount) before the planarization material 310 becomes softened in response to the heat (e.g., to allow for improved de-gassing). That is, the distance between the heat source 430 and the carrier 420 can be controlled to also control the transfer of heat (e.g., rate of heat transfer) to the carrier 420 from the heat source 430. Then, as shown in the diagram 400g of FIG. 4G, in order to speed up the softening of the planarization material 310, the pins 435 can be retracted such that carrier 420 is brought closer to heat source 430. For example, the pins 435 can be completely retracted such that the carrier 420 is in direct contact with the heat source 430 such that the transfer of heat to the layers of the stack can be expedited.

In some implementations, the stack of layers, and therefore the planarization material 310, can be heated without the use of the pins 435. For example, if the softening or melting point of the planarization material 310 is high, then the pins 435 or extending the pins 435 may not be needed. In such a case, the carrier 420 can be placed directly in contact with the heat source 430. Alternatively, the carrier 420 may not be used at all, in which case the stack of layers can be placed directly on the heat source 430 (or directly on the pins 435 if used).

In general, the heat source 430 is used to heat the carrier 420, which in turn heats the stack of layers that includes one or more layers of the planarization material 310. When the temperature of the heat source 430 is sufficiently high, the layer or layers of the planarization material 310 can begin to soften (e.g., when their temperature reaches their softening point, which is the point at which materials begin to soften). When used, the application of the vacuum (e.g., also refer to as pulling vacuum) causes air, gas, and/or moisture to be removed from the bag or chamber such that the planarization material 310 does not melt or sag unexpectedly, and/or to avoid air bubbles as the planarization material 310 softens or melts. At this point, force can be applied to the stack of layers. That is, force can be applied to the stack of layers when the temperature of the planarization material 310 approaches or reaches its softening point. When different types of planarization material 310 are used in the stack of layers, the application of force may depend on the different softening points of the different types of the planarization material 310.

In connection with the application of force to the stack of layers, force can be applied to the release layer 410a. The source of the force can be based on the conditions used, one example being the type of bag or chamber being used. In some implementations, a silicone diaphragm can be used to press down on the release layer 410a to provide the force. The silicone diaphragm can descend or approach the release layer 410a upon the application of the vacuum or heat, or both. By applying the force, the form of the now softened planarization material 310 can be changed to allows for the (partial or complete) encapsulation or embedding of the PV layer 110 with the protrusion 120 within of the planarization material 310. For example, a diagram 400h of FIG. 4H shows the PV layer 110 with the protrusion 120 suspended (e.g., surrounded, embedded) within the planarization material 310. The planarized PV layer in FIG. 5H can be the result of the softening and/or melting of two layers of the planarization material 310 (e.g., one layer on top of the PV layer 110 and another layer below the PV layer 110) and the force applied to the stack of layers to cause the softened and/or melted planarization material 310 to surround or embed the PV layer 110 with the protrusion 120.

FIG. 4I shows a diagram 400i in which another example of a planarized PV layer is described. In this example, the planarized PV layer can be the result of the softening and/or melting of a single layer of the planarization material 310 (e.g., a layer on top of the PV layer 110) and the force applied to the stack of layers to cause the softened and/or melted planarization material 310 to surround or embed a top portion of the PV layer 110 with the protrusion 120.

FIG. 4J shows a diagram 400j in which another example of a planarized PV layer is described. In this example, the planarized PV layer can be the result of the softening and/or melting of two layers of the planarization material 310 (e.g., one layer on top of the PV layer 110 and another layer below the PV layer 110) and the force applied to the stack of layers to cause the softened and/or melted planarization material 310 to surround or embed the PV layer 110 with the protrusion 120d on top and the protrusion 120e at the bottom.

As shown in FIGS. 4H-4J, the application of force when the planarization material 310 is malleable after reaching its softening point allows for the physical form of the planarization material 310 to be modified through the use of heat and force such that the PV layer 110 with the protrusion(s) 120 can be at least partially (if not completely) embedded within the planarization material 310.

The application of force as described above can be controlled during different phases of the process of forming a planarized PV layer. For example, the force can first be applied when the planarization material 310 reaches its softening point. At this point, the planarization material 310 has softened and is more malleable to applied force, and can therefore change its form (e.g., deform) from the application of the force. As more force is applied, the thermal conduction of heat to the planarization material 310 increases along, which in turn causes the temperature of the planarization material 310 to increase. The force can be maintained until the melting point of the planarization material 310 is about to be reached (e.g., just before it is reached) or until it has been reached. At that point, the application of force can be stopped, or alternatively, the application of force can be maintained to allow the planarization material 310 to better conform to surfaces, to improve adhesion between the layers of the stack, and/or to allow for proper curing of the planarization material 310 if thermosets are used.

The amount of force and/or the rate of application of force can also be adjusted during the process of forming a planarized PV layer or intermediate PV component. For example, a first, low amount of force can be applied to the release layer 410a to reduce or prevent the deformation or wrinkling of a layer of the planarization material 310 placed over the PV layer 110 with the protrusion 120 as the material temperature increases and approaches its softening point. Then, a second, higher amount of force can be applied. The second amount of force can be slowly ramped, or increased, at a rate such that the various layers of the planarization material 310 can deform and flow to surround or embed the PV layer 110 with the protrusion 120 within planarization material 310.

If the various layers of the planarization material 310 are made of the same material, then the planarization material 310 that ends up surrounding the PV layer 110 with the protrusion 120 can be a monolithic structure (see e.g., FIG. 4H). Alternatively, as described above, different layers of the planarization material 130 can be made of different materials.

Following the processes described above in connection with FIGS. 4E-4J, the stack of layers can be removed from the carrier 420 (if used) and the release layers 410a and 410b can also be removed. The structure shown in FIG. 4H represents an example of a planarized PV layer that remains from the stack of layers after the removal of the carrier 420 and/or the release layers 410a and 410b. This example is based on the scenario in which two layers of the planarization material 310 were used to surround the PV layer 110 with the protrusion 120. The structure shown in FIG. 4I represents another example of a planarized PV layer that remains from the stack of layers after the removal of the carrier 420 and/or the release layers 410a and 410b. This example is based on the scenario in which a single layer of the planarization material 310 was used to surround a top portion of the PV layer 110 with the protrusion 120. The structure shown in FIG. 4J represents another example of a planarized PV layer that remains from the stack of layers after the removal of the carrier 420 and/or the release layers 410a and 410b. This example is based on the scenario in which two layers of the planarization material 310 were used to surround the PV layer 110 with the protrusions 120d and 120e.

The planarized PV layers or intermediate PV components shown in FIGS. 4H-4J are available for assembly or integration into another stack of layers or an optoelectronic component. For example, the planarized PV layers shown in FIGS. 4H-4J can then be assembled with other layers and subjected to additional processes, including vacuum processes.

The amount of force, temperature, pressure, and rates of change of these variables can be dependent upon the type of material used for the layer or layers of the planarization material 310. For example, a layer of PVB might have different variables and rates of change than a layer of EVA.

Regarding PVB, a 0.1 millimeter (mm) thick PVB thermoplastic can be used for a layer of the planarization material 310. The PVB layer is initially placed in a vacuum at 1,000 millibar (mbar) with the heat source 430 providing heat at 150° C. Next, the pressure is reduced to close to 0 mbar over a 600 seconds period. This allows for the de-gassing and relatively slow heating of the PVB—the pins 435 of the heat source 430 can be extended such that the carrier 420 is positioned away from the heat source 430 for the slow heating. Then, over the following ten seconds, the pins 435 can be retracted such that the carrier 420 is positioned in direct or close contact with the heat source 430. For the next 120 seconds, a force is applied at 1,000 mbar of press pressure. For the following 300 seconds, the force is maintained to allow for the PVB layer to melt and flow around the PV layer 110 with the protrusion 120 such that they are embedded within the planarization material 310 (e.g., the PVB).

On the other hand, if a 0.1 mm thick EVA thermoset is used for a layer of the planarization material 310, the variables may be different from those mentioned above. In one such example, the EVA layer can be placed within a vacuum at 1,000 mbar and the heat source 530 provides heat at 150° C. Then, for the first 360 seconds, the pressure is reduced to close to 0 mbar to allow for the de-gassing and to slow down the heating of the EVA. For the following 10 seconds, the pins 535 can be retracted. Next, for 90 seconds, a 1,000 mbar of pressure is applied to the stack of layers that includes the EVA layer. This is followed by 720 seconds of additional application of the press pressure to allow for the EVA layer to melt and flow around the PV layer 110 with the protrusion 120 such that they are embedded within the planarization material 310 (e.g., the EVA).

Once the planarized PV layers or intermediate PV components described above are assembled as part of a stack of layers of an optoelectronic component they can be used for various industrial applications. The stack of layers of the optoelectronic component can include external layers that provide operational and/or environmental protection, such as the first layer 130a and the second layer 130b described above.

In FIG. 5, a diagram 500 illustrates a top view of a structure or optoelectronic component in which a planarized PV layer has been laminated with protecting layers. In this example, a PV layer 110 is shown to include two PV cells 510a and 510b, although the number of PV cells is merely provided for illustrative purposes and the PV layer 110 can include a larger number of PV cells. Also shown is a protrusion 120a that can correspond to a negative bus, busbar, or contact, and a protrusion 120b that can correspond to a positive bus, busbar, or contact. The PV layer 110 and the protrusions 120a and 120b can be surrounded by the planarization material 310 in the various ways described above to form a planarized PV layer or intermediate PV component. The planarized PV layer is then protected on one side with the first layer 130a and on the other side (not shown) with the second layer 130b. Details regarding different types of materials that can be used for these protective layers have been described above in connection with the first layer 130a and the second layer 130b. Although not shown, the perimeter of the structure or optoelectronic component in FIG. 5 can be sealed after assembly is complete.

An aspect of the structures or optoelectronic components described above is that they have a flat shape. For example, the protective layers (e.g., the first layer 130a and the second layer 130b) that in a way define the shape of the structure or optoelectronics component are flat. The planarization techniques described herein, however, are not limited to such shapes and instead can apply to different types of shapes since these techniques are intended to address localized surface irregularities (e.g., protrusions, depressions) rather than shape variations over the entire surface of the PV layer. As such, the planarization techniques described herein can also apply to structures or optoelectronic components that have curved and non-uniform shapes.

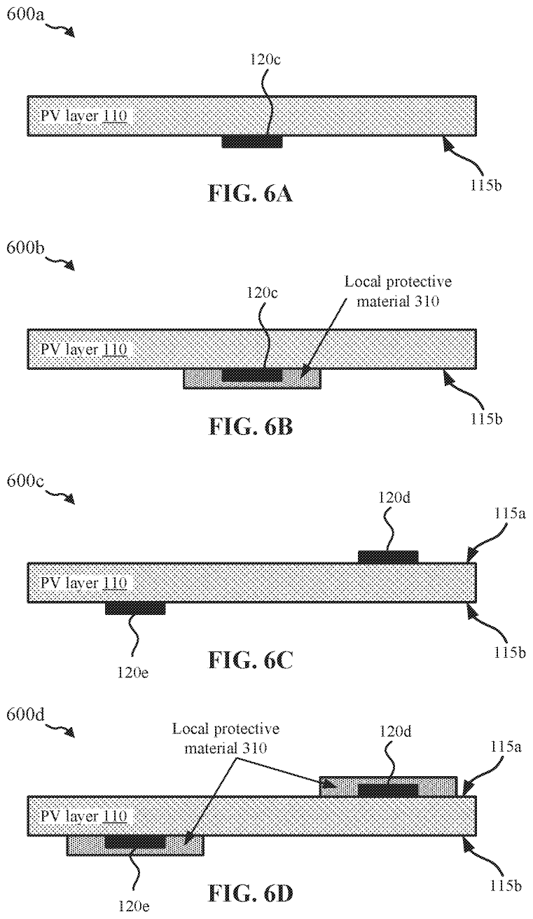

FIGS. 6A-6D provide examples of localized planarization for different topographies of PV layers. In FIG. 6A, a diagram 600a shows the PV layer 110 having the protrusion 120c on the second surface 115b (e.g., on a bottom surface) of the PV layer 110. In FIG. 6B, a diagram 600b shows how the planarization material 310 is applied locally to cover only a small portion of the second surface 115b that surrounds the protrusion 120. In this regard, a single, localized layer of the planarization material 310 can be applied and heated to cover the protrusion 120 and not the entire second surface 115b of the PV layer 110. The localized application of the planarization material 130 is sufficient to distribute any forces apply to avoid damage to the PV layer 110 if a force is applied where the protrusion is located.

In FIG. 6C, a diagram 600c shows the PV layer 110 having the protrusion 120d on the first surface 115a (e.g., on a top surface) and the protrusion 120e on the second surface 115b (e.g., on a bottom surface) of the PV layer 110. In FIG. 6D, a diagram 600d shows how the planarization material 310 is applied locally to cover only a small portion of the first surface 115a that surrounds the protrusion 120d and only a small portion of the second surface 115b that surrounds the protrusion 120e. In this regard, a single, localized layer of the planarization material 310 can be applied and heated to cover the protrusion 120d and not the entire first surface 115a of the PV layer 110. Similarly for the protrusion 120e and the second surface 115b.

The effect of using a localized planarization technique as described in FIGS. 6A-6D can be similar to that of using a general planarization technique as described above. That is, a localized planarization technique can also reduce the incidence of cracks, defects, and/or shunts produced during certain processes, including autoclave lamination processes, improving overall performance and/or manufacturing yields.

An aspect of some of the examples described above is that the surface irregularities or topographical height changes illustrated mainly concern different types of protrusions on the topography of the PV cell. The planarization techniques described herein, however, are not so limited and the same or similar approaches described above in connection with protrusions can also apply to surface irregularities or topographical height changes that include depressions (e.g., whole or partial cavities), protrusions, a combination of depressions and protrusions on the topography of the PV cell, or height changes associated with overlapping PV layers.

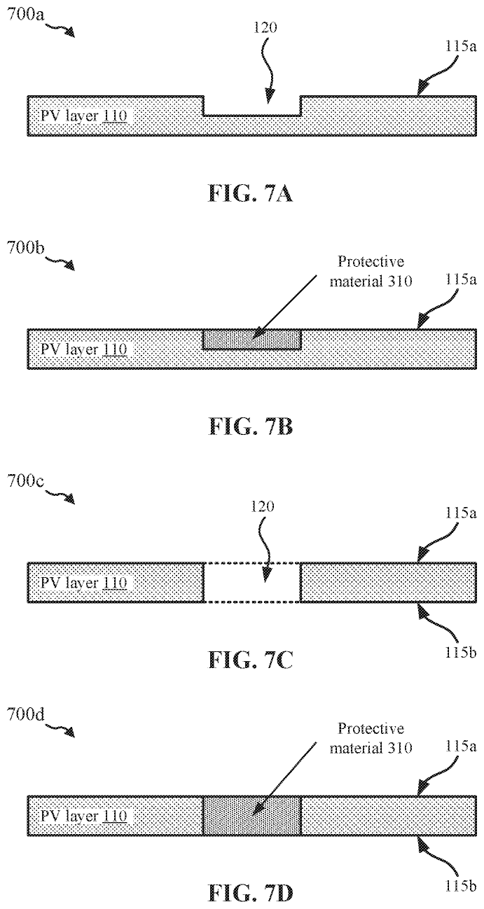

FIGS. 7A-7D illustrate other examples of localized planarization for different topographies of PV layers. In FIG. 7A, a diagram 700a shows the PV layer 110 having a surface irregularity or topographical height change 120 corresponding to a depression (e.g., surface cavity) on the first surface 115a (e.g., on a top surface) of the PV layer 110. In FIG. 7B, a diagram 700b shows how the planarization material 310 is applied locally to cover the surface irregularity 120 (e.g., cover the surface cavity) and have the first surface 115a substantially flat. In this regard, a single, localized layer of the planarization material 310 can be applied and heated to cover the depression associated with the surface irregularity 120.

In FIG. 7C, a diagram 700c shows the PV layer 110 having a surface irregularity or topographical height change 120 corresponding to a depression (e.g., hole, joint, or gap) from the first surface 115a (e.g., a top surface) through to the second surface 115b (e.g., a bottom surface). In FIG. 7D, a diagram 700d shows how the planarization material 310 is applied locally to cover the surface irregularity 120 (e.g., cover the hole, joint, or gap) and have both the first surface 115a and the second surface 115b substantially flat. In this regard, one or two localized layers of the planarization material 310 can be applied and heated to cover the depression associated with the surface irregularity 120.

The effect of using a localized planarization technique in connection with depressions on a PV layer as described in FIGS. 7A-7D can be similar to that of using a general planarization technique as described above. That is, a localized planarization technique applied to a depression can also reduce the incidence of cracks, defects, and/or shunts produced during certain processes, including autoclave lamination processes, improving overall performance and/or manufacturing yields.

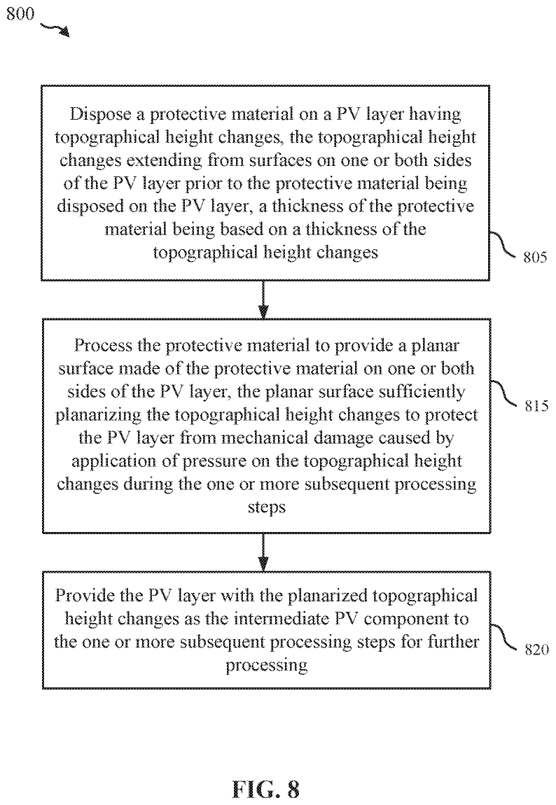

FIG. 8 shows a flow diagram describing a method or process 800 for producing an intermediate PV component protected from mechanical damage.

At 805, the method 800 includes disposing a protective material (e.g., the planarization material 310) on a PV layer (e.g., the PV layer 110) having topographical height changes (e.g., irregularities or height changes 120), the topographical height changes extending from surfaces on one or both sides of the PV layer prior to the protective material being disposed on the PV layer, a thickness of the protective material being based on a thickness of the topographical height changes.

At 810, the method 800 includes processing the protective material to provide a planar surface made of the protective material on one or both sides of the PV layer, the planar surface sufficiently planarizing the topographical height changes to protect the PV layer from mechanical damage caused by application of pressure on the topographical height changes during the one or more subsequent processing steps.

At 815, the method 800 includes providing the PV layer with the planarized topographical height changes as the intermediate PV component to the one or more subsequent processing steps for further processing (e.g., to form another stack of layers or an electronic component).

In an aspect of the method 800, the topographical height changes include height changes formed by an edge of another PV layer overlapping a portion of the PV layer.

In an aspect of the method 800, the topographical height changes include one or more gaps between solar cells in the PV layer.

In an aspect of the method 800, the topographical height changes include one or more surface depressions.

In an aspect of the method 800, the topographical height changes include PV layer structural protrusions. The PV layer structural protrusions include one or more bus bars, one or more electrode fingers, one or more contacts, or a combination thereof.

In an aspect of the method 800, disposing the protective material on the PV layer includes disposing a layer of the protective material on a top side of the PV layer, disposing a layer of the protective material on a bottom side of the PV layer, or both.

In an aspect of the method 800, processing the protective material includes modifying a physical form of one or more layers of the protective material disposed on the PV layer. The modifying of the physical form of the one or more layers of the protective material includes softening the one or more layers of the protective material to at least partially embed the PV layer within the protective material. At least partially embedding the PV layer within the protective material includes surrounding a surface on a top side of the PV layer with the protective material. Alternatively, at least partially embedding the PV layer within the protective materials includes surrounding a surface on a top side of the PV layer and a surface on a bottom side of the PV layer with the protective material.

In an aspect of the method 800, the one or more subsequent processing steps apply pressure to one or both sides of the PV layer.

In an aspect of the method 800, a top side of the PV layer is a front side of the PV layer for capturing light energy and a bottom side of the PV layer is a back side of the PV layer.

In an aspect of the method 800, the method 800 further includes providing as the PV layer a thin film PV material. The thin film PV material includes one or more of cadmium telluride (CdTe), copper indium gallium diselenide (CIGS), amorphous thin-film silicon (a-Si), gallium arsenide (GaAs, GaInP/GaAs/Ge), or perovskite.

In an aspect of the method 800, the method 800 further includes providing the PV layer, wherein the PV layer includes, gallium arsenide (GaAs, GaInP/GaAs/Ge), crystalline silicon (c-Si) made of multicrystalline silicon or monocrystalline silicon.

In an aspect of the method 800, the method 800 further includes providing the PV layer, wherein the PV layer includes a heterojunction with intrinsic thin layer (HIT) structure having a thin crystalline silicon layer surrounded by one or more ultra-thin amorphous silicon layers.

In an aspect of the method 800, the method 800 further includes providing the PV layer, wherein the PV layer includes one or more solar cells in electrical communication, or one or more solar modules in electrical communication.

In an aspect of the method 800, the protective material includes one or more of a thermoplastic or a thermoset.

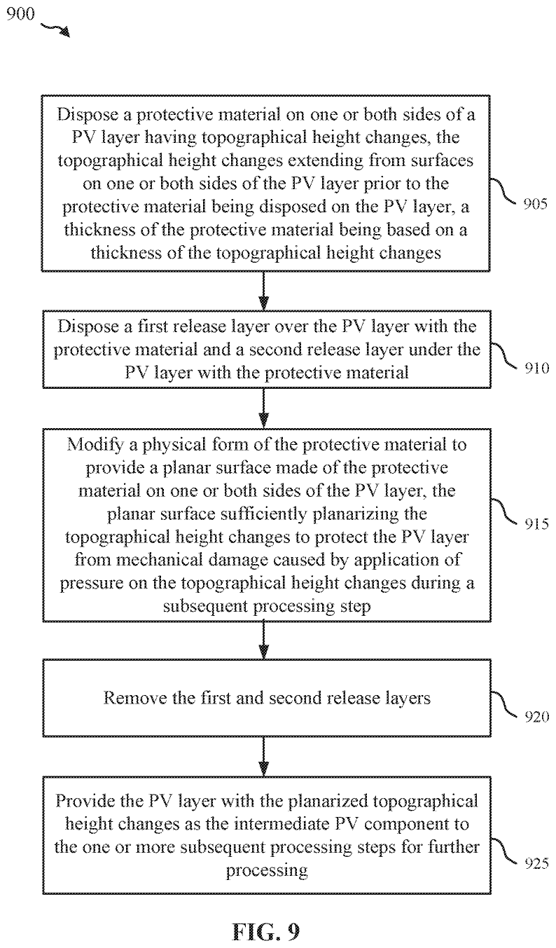

FIG. 9 shows a flow diagram describing another method or process 900 for producing an intermediate PV component protected from mechanical damage.

At 905, the method 900 includes disposing a protective material (e.g., the planarization material 310) on one or both sides of a PV layer (e.g., the PV layer 110) having topographical height changes (e.g., irregularities or height changes 120), the topographical height changes extending from surfaces on one or both sides of the PV layer prior to the protective material being disposed on the PV layer, and a thickness of the protective material being based on a thickness of the topographical height changes.

At 910, the method 900 includes disposing a first release layer over the PV layer with the protective material and a second release layer under the PV layer with the protective material (e.g., the release layers 410a, 410b).

At 915, the method 900 includes modifying a physical form of the protective material to provide a planar surface made of the protective material on one or both sides of the PV layer, the planar surface sufficiently planarizing the topographical height changes to protect the PV layer from mechanical damage caused by application of pressure on the topographical height changes during a subsequent processing step.

At 920, the method 900 includes removing the first and second release layers.

At 925, the method 900 includes providing the PV layer with the planarized topographical height changes as the intermediate PV component to the one or more subsequent processing steps for further processing (see e.g., FIGS. 3A-3H).

In an aspect of the method 900, modifying the physical form of the protective material includes a reactive heatless process, a carrier-based heating process, or a carrier-less heating process.

In an aspect of the method 900, disposing the protective material on the one or both sides of the PV layer includes: disposing a first layer of the protective material on a top side of the PV layer; and disposing a second layer of the protective material on a bottom side of the PV layer, and where modifying the physical form of the protective material to provide the planar surface made of the protective material on one or both sides of the PV layer includes modifying a physical form of the first layer of the protective material and the second layer of the protective material.

In an aspect of the method 900, the topographical height changes include height changes formed by an edge of another PV layer overlapping a portion of the PV layer.

In an aspect of the method 900, the topographical height changes include one or more gaps between solar cells in the PV layer.

In an aspect of the method 900, the topographical height changes include one or more surface depressions.

In an aspect of the method 900, the topographical height changes include PV layer structural protrusions.

In an aspect of the method 900, the PV layer structural protrusions include one or more bus bars, one or more electrode fingers, one or more contacts, or a combination thereof.

Based on the various examples of planarized PV layers and the methods described above for producing intermediate PV components from such planarized PV layers, the present disclosure therefore describes and enables a light-capturing component protected from mechanical damage that is be provided to one or more subsequent processing steps. Such light-capturing component includes a photovoltaic (PV) layer and a protective material disposed on the PV layer, where the PV layer has topographical height changes, the topographical height changes extending from surfaces on one or both sides of the PV layer prior to the protective material being disposed on the PV layer, a thickness of the protective material being based on a thickness of the topographical height changes, and where the protective material is processed to provide a planar surface made of the protective material on one or both sides of the PV layer, the planar surface sufficiently planarizing the topographical height changes to protect the PV layer from mechanical damage caused by application of pressure on the topographical height changes during the subsequent processing step.

In an aspect of the light-capturing component, the topographical height changes include height changes formed by an edge of another PV layer overlapping a portion of the PV layer.

In an aspect of the light-capturing component, the topographical height changes include one or more gaps between solar cells in the PV layer.

In an aspect of the light-capturing component, the topographical height changes include one or more surface depressions.

In an aspect of the light-capturing component, the topographical height changes include PV layer structural protrusions. The PV layer structural protrusions include one or more bus bars, one or more electrode fingers, one or more contacts, or a combination thereof.

In an aspect of the light-capturing component, the PV layer is at least partially embedded within the protective material.

In an aspect of the light-capturing component, the protective material surrounds at least the surface on a top side of the PV layer.

In an aspect of the light-capturing component, the protective material surrounds at least the surface on a bottom side of the PV layer.

In an aspect of the light-capturing component, the protective material surrounds the surface on a top side of the PV layer and the surface on a bottom side of the PV layer.

In an aspect of the light-capturing component, the protective material covers a portion of a top side of the PV layer, a portion of a bottom side of the PV layer, or both.

In an aspect of the light-capturing component, a top side of the PV layer is a front side of the PV layer for capturing light energy and a bottom side of the PV layer is a back side of the PV layer.

In an aspect of the light-capturing component, the PV layer includes a thin film PV material. The thin film PV material includes one or more of cadmium telluride (CdTe), copper indium gallium diselenide (CIGS), amorphous thin-film silicon (a-Si), gallium arsenide (GaAs, gallium arsenide (GaAs, GaInP/GaAs/Ge)), or perovskite.

In an aspect of the light-capturing component, the PV layer includes gallium arsenide (GaAs, GaInP/GaAs/Ge), crystalline silicon (c-Si) made of multicrystalline silicon or monocrystalline silicon.

In an aspect of the light-capturing component, the PV layer includes a heterojunction with intrinsic thin layer (HIT) structure having a thin crystalline silicon layer surrounded by one or more ultra-thin amorphous silicon layers.

In an aspect of the light-capturing component, the PV layer includes one or more solar cells in electrical communication, or one or more solar modules in electrical communication.

In an aspect of the light-capturing component, the protective material includes one or more of a thermoplastic or a thermoset.

In an aspect of the light-capturing component, the light-capturing component is an intermediate industrial component and is configured to be assembled with other components as part of a manufacturing process that includes the one or more subsequent processing steps.

Each of the features described above in connection with the figures, the methods 800 and 900, and the light-capturing component can be implemented individually or in some combination for planarizing a PV layer and processing the planarized PV layer or intermediate PV component to fabricate, assemble, or manufacture an optoelectronic component or structure that is free, or relatively free, of cracks, defects, and/or shunts.

Additional Implementations

An example method for producing an intermediate photovoltaic (PV) component protected from mechanical damage in one or more subsequent processing steps, the method comprising: disposing a protective material on a PV layer having topographical height changes, the topographical height changes extending from surfaces on one or both sides of the PV layer prior to the protective material being disposed on the PV layer, a thickness of the protective material being based on a thickness of the topographical height changes; processing the protective material to provide a planar surface made of the protective material on one or both sides of the PV layer, the planar surface sufficiently planarizing the topographical height changes to protect the PV layer from mechanical damage caused by application of pressure on the topographical height changes during the one or more subsequent processing steps; and providing the PV layer with the planarized topographical height changes as the intermediate PV component to the one or more subsequent processing steps for further processing.

The above example method, wherein the topographical height changes include height changes formed by an edge of another PV layer overlapping a portion of the PV layer.

One or more of the above example methods, wherein the topographical height changes include one or more gaps between solar cells in the PV layer.

One or more of the above example methods, wherein the topographical height changes include one or more surface depressions.

One or more of the above example methods, wherein the topographical height changes include PV layer structural protrusions.

One or more of the above example methods, wherein the PV layer structural protrusions include one or more bus bars, one or more electrode fingers, one or more contacts, or a combination thereof.

One or more of the above example methods, wherein disposing the protective material on the PV layer includes disposing a layer of the protective material on a top side of the PV layer, disposing a layer of the protective material on a bottom side of the PV layer, or both.

One or more of the above example methods, wherein processing the protective material includes modifying a physical form of one or more layers of the protective material disposed on the PV layer.

One or more of the above example methods, wherein modifying the physical form of the one or more layers of the protective material includes softening the one or more layers of the protective material to at least partially embed the PV layer within the protective material.

One or more of the above example methods, wherein at least partially embedding the PV layer within the protective material includes surrounding a surface on a top side of the PV layer with the protective material.

One or more of the above example methods, wherein at least partially embedding the PV layer within the protective materials includes surrounding a surface on a top side of the PV layer and a surface on a bottom side of the PV layer with the protective material.

One or more of the above example methods, wherein the one or more subsequent processing steps apply pressure to one or both sides of the PV layer.

One or more of the above example methods, wherein a top side of the PV layer is a front side of the PV layer for capturing light energy and a bottom side of the PV layer is a back side of the PV layer.

One or more of the above example methods, further comprising providing as the PV layer a thin film PV material.

One or more of the above example methods, wherein the thin film PV material includes one or more of cadmium telluride (CdTe), copper indium gallium diselenide (CIGS), amorphous thin-film silicon (a-Si), gallium arsenide (GaAs, GaInP/GaAs/Ge), or perovskite.

One or more of the above example methods, further comprising providing the PV layer, wherein the PV layer includes, gallium arsenide (GaAs, GaInP/GaAs/Ge), crystalline silicon (c-Si) made of multicrystalline silicon or monocrystalline silicon.

One or more of the above example methods, further comprising providing the PV layer, wherein the PV layer includes a heterojunction with intrinsic thin layer (HIT) structure having a thin crystalline silicon layer surrounded by one or more ultra-thin amorphous silicon layers.

One or more of the above example methods, further comprising providing the PV layer, wherein the PV layer includes one or more solar cells in electrical communication, or one or more solar modules in electrical communication.

One or more of the above example methods, wherein the protective material includes one or more of a thermoplastic or a thermoset.

An example light-capturing component protected from mechanical damage and to be provided to one or more subsequent processing steps, comprising: a photovoltaic (PV) layer; and a protective material disposed on the PV layer, wherein the PV layer has topographical height changes, the topographical height changes extending from surfaces on one or both sides of the PV layer prior to the protective material being disposed on the PV layer, a thickness of the protective material being based on a thickness of the topographical height changes, and wherein the protective material is processed to provide a planar surface made of the protective material on one or both sides of the PV layer, the planar surface sufficiently planarizing the topographical height changes to protect the PV layer from mechanical damage caused by application of pressure on the topographical height changes during the subsequent processing step.

The above example light-capturing component, wherein the topographical height changes include height changes formed by an edge of another PV layer overlapping a portion of the PV layer.

One or more of the above example light-capturing components, wherein the topographical height changes include one or more gaps between solar cells in the PV layer.

One or more of the above example light-capturing components, wherein the topographical height changes include one or more surface depressions.

One or more of the above example light-capturing components, wherein the topographical height changes include PV layer structural protrusions.

One or more of the above example light-capturing components, wherein the PV layer structural protrusions include one or more bus bars, one or more electrode fingers, one or more contacts, or a combination thereof.

One or more of the above example light-capturing components, wherein the PV layer is at least partially embedded within the protective material.

One or more of the above example light-capturing components, wherein the protective material surrounds at least the surface on a top side of the PV layer.

One or more of the above example light-capturing components, wherein the protective material surrounds at least the surface on a bottom side of the PV layer.

One or more of the above example light-capturing components, wherein the protective material surrounds the surface on a top side of the PV layer and the surface on a bottom side of the PV layer.

One or more of the above example light-capturing components, wherein the protective material covers a portion of a top side of the PV layer, a portion of a bottom side of the PV layer, or both.

One or more of the above example light-capturing components, wherein a top side of the PV layer is a front side of the PV layer for capturing light energy and a bottom side of the PV layer is a back side of the PV layer.

One or more of the above example light-capturing components, wherein the PV layer includes a thin film PV material.

One or more of the above example light-capturing components, wherein the thin film PV material includes one or more of cadmium telluride (CdTe), copper indium gallium diselenide (CIGS), amorphous thin-film silicon (a-Si), gallium arsenide (GaAs, gallium arsenide (GaAs, GaInP/GaAs/Ge)), or perovskite.

One or more of the above example light-capturing components, wherein the PV layer includes gallium arsenide (GaAs, GaInP/GaAs/Ge), crystalline silicon (c-Si) made of multicrystalline silicon or monocrystalline silicon.

One or more of the above example light-capturing components, wherein the PV layer includes a heterojunction with intrinsic thin layer (HIT) structure having a thin crystalline silicon layer surrounded by one or more ultra-thin amorphous silicon layers.

One or more of the above example light-capturing components, wherein the PV layer includes one or more solar cells in electrical communication, or one or more solar modules in electrical communication.

One or more of the above example light-capturing components, wherein the protective material includes one or more of a thermoplastic or a thermoset.

One or more of the above example light-capturing components, wherein the light-capturing component is an intermediate industrial component and is configured to be assembled with other components as part of a manufacturing process that includes the one or more subsequent processing steps.

An example second method for producing an intermediate photovoltaic (PV) component protected from mechanical damage in one or more subsequent processing steps, the method comprising: disposing a protective material on one or both sides of a PV layer having topographical height changes, the topographical height changes extending from surfaces on one or both sides of the PV layer prior to the protective material being disposed on the PV layer, a thickness of the protective material being based on a thickness of the topographical height changes; disposing a first release layer over the PV layer with the protective material and a second release layer under the PV layer with the protective material; modifying a physical form of the protective material to provide a planar surface made of the protective material on one or both sides of the PV layer, the planar surface sufficiently planarizing the topographical height changes to protect the PV layer from mechanical damage caused by application of pressure on the topographical height changes during a subsequent processing step; removing the first and second release layers; and providing the PV layer with the planarized topographical height changes as the intermediate PV component to the one or more subsequent processing steps for further processing.

The above example second method, wherein modifying the physical form of the protective material includes a reactive heatless process, a carrier-based heating process, or a carrier-less heating process.

One or more of the above example second methods, wherein disposing the protective material on the one or both sides of the PV layer includes: disposing a first layer of the protective material on a top side of the PV layer; and disposing a second layer of the protective material on a bottom side of the PV layer, wherein modifying the physical form of the protective material to provide the planar surface made of the protective material on one or both sides of the PV layer includes modifying a physical form of the first layer of the protective material and the second layer of the protective material.

One or more of the above example second methods, wherein the topographical height changes include height changes formed by an edge of another PV layer overlapping a portion of the PV layer.

One or more of the above example second methods, wherein the topographical height changes include one or more gaps between solar cells in the PV layer.

One or more of the above example second methods, wherein the topographical height changes include one or more surface depressions.

One or more of the above example second methods, wherein the topographical height changes include PV layer structural protrusions.

One or more of the above example second methods, wherein the PV layer structural protrusions include one or more bus bars, one or more electrode fingers, one or more contacts, or a combination thereof.

The above description of various embodiments of the claimed subject matter has been provided for the purposes of illustration and description. It is not intended to be exhaustive or to limit the claimed subject matter to the precise forms disclosed. Many modifications and variations will be apparent to one skilled in the art. Embodiments were chosen and described in order to best describe certain principles and practical applications, thereby enabling others skilled in the relevant art to understand the subject matter, the various embodiments and the various modifications that are suited to the particular uses contemplated.

Although the above Detailed Description describes certain embodiments and the best mode contemplated, no matter how detailed the above appears in text, the embodiments can be practiced in many ways. Details of the systems and methods may vary considerably in their implementation details while still being encompassed by the specification. As noted above, particular terminology used when describing certain features or aspects of various embodiments should not be taken to imply that the terminology is being redefined herein to be restricted to any specific characteristics, features, or aspects of the disclosed technique with which that terminology is associated. In general, the terms used in the following claims should not be construed to limit the disclosure to the specific embodiments disclosed in the specification, unless those terms are explicitly defined herein. Accordingly, the actual scope of the technique encompasses not only the disclosed embodiments but also all equivalent ways of practicing or implementing the embodiments under the claims.

The language used in the specification has been principally selected for readability and instructional purposes, and it may not have been selected to delineate or circumscribe the inventive subject matter. It is therefore intended that the scope of the technique be limited not by this Detailed Description, but rather by any claims that issue on an application based hereon. Accordingly, the disclosure of various embodiments is intended to be illustrative, but not limiting, of the scope of the embodiments, which is set forth in the following claims.

From the foregoing, it will be appreciated that specific embodiments of the invention have been described herein for purposes of illustration, but that various modifications may be made without deviating from the scope of the invention. Accordingly, the invention is not limited except as by the appended claims.

What is claimed is:

1. A method for producing an intermediate photovoltaic (PV) component protected from mechanical damage in one or more subsequent processing steps, the method comprising:
disposing a protective material on a PV layer having topographical height changes, the topographical height changes extending from surfaces on one or both sides of the PV layer prior to the protective material being disposed on the PV layer, a thickness of the protective material being based on a thickness of the topographical height changes;
processing the protective material to provide a planar surface made of the protective material on one or both sides of the PV layer, the planar surface sufficiently planarizing the topographical height changes to protect the PV layer from mechanical damage caused by application of pressure on the topographical height changes during the one or more subsequent processing steps; and
providing the PV layer with the planarized topographical height changes as the intermediate PV component to the one or more subsequent processing steps for further processing.

2. The method of claim 1, wherein the topographical height changes include height changes formed by an edge of another PV layer overlapping a portion of the PV layer.

3. The method of claim 1, wherein the topographical height changes include one or more gaps between solar cells in the PV layer.

4. The method of claim 1, wherein the topographical height changes include one or more surface depressions.

5. The method of claim 1, wherein the topographical height changes include PV layer structural protrusions.

6. The method of claim 5, wherein the PV layer structural protrusions include one or more bus bars, one or more electrode fingers, one or more contacts, or a combination thereof.

7. The method of claim 1, wherein disposing the protective material on the PV layer includes disposing a layer of the protective material on a top side of the PV layer, disposing a layer of the protective material on a bottom side of the PV layer, or both.

8. A light-capturing component protected from mechanical damage and to be provided to one or more subsequent processing steps, comprising:
a photovoltaic (PV) layer; and
a protective material disposed on the PV layer,
wherein the PV layer has topographical height changes, the topographical height changes extending from surfaces on one or both sides of the PV layer prior to the protective material being disposed on the PV layer, a thickness of the protective material being based on a thickness of the topographical height changes, and
wherein the protective material is processed to provide a planar surface made of the protective material on one or both sides of the PV layer, the planar surface sufficiently planarizing the topographical height changes to protect the PV layer from mechanical damage caused by application of pressure on the topographical height changes during the subsequent processing step.

9. The light-capturing component of claim 8, wherein the topographical height changes include height changes formed by an edge of another PV layer overlapping a portion of the PV layer.

10. The light-capturing component of claim 8, wherein the topographical height changes include one or more gaps between solar cells in the PV layer.

11. The light-capturing component of claim 8, wherein the topographical height changes include one or more surface depressions.

12. The light-capturing component of claim 8, wherein the topographical height changes include PV layer structural protrusions.

13. The light-capturing component of claim 12, wherein the PV layer structural protrusions include one or more bus bars, one or more electrode fingers, one or more contacts, or a combination thereof.

14. The light-capturing component of claim 8, wherein the PV layer is at least partially embedded within the protective material.

15. A method for producing an intermediate photovoltaic (PV) component protected from mechanical damage in one or more subsequent processing steps, the method comprising:
disposing a protective material on one or both sides of a PV layer having topographical height changes, the topographical height changes extending from surfaces on one or both sides of the PV layer prior to the protective material being disposed on the PV layer, a thickness of the protective material being based on a thickness of the topographical height changes;
disposing a first release layer over the PV layer with the protective material and a second release layer under the PV layer with the protective material;
modifying a physical form of the protective material to provide a planar surface made of the protective material on one or both sides of the PV layer, the planar surface sufficiently planarizing the topographical height changes to protect the PV layer from mechanical damage caused by application of pressure on the topographical height changes during a subsequent processing step;
removing the first and second release layers; and
providing the PV layer with the planarized topographical height changes as the intermediate PV component to the one or more subsequent processing steps for further processing.

16. The method of claim 15, wherein modifying the physical form of the protective material includes a reactive heatless process, a carrier-based heating process, or a carrier-less heating process.

17. The method of claim 15, wherein disposing the protective material on the one or both sides of the PV layer includes:
disposing a first layer of the protective material on a top side of the PV layer; and
disposing a second layer of the protective material on a bottom side of the PV layer,
wherein modifying the physical form of the protective material to provide the planar surface made of the protective material on one or both sides of the PV layer includes modifying a physical form of the first layer of the protective material and the second layer of the protective material.

18. The method of claim 15, wherein the topographical height changes include height changes formed by an edge of another PV layer overlapping a portion of the PV layer.

19. The method of claim 15, wherein the topographical height changes include one or more gaps between solar cells in the PV layer.

20. The method of claim 15, wherein the topographical height changes include one or more surface depressions.
